(19) United States
(12) Patent Application Publication
(10) Pub. No.: US 2022/0199871 A1
(43) Pub. Date: Jun. 23, 2022

(54) BEAM-SHAPING SECONDARY OPTICAL COMPONENTS FOR MICRO LIGHT EMITTING DIODES

(71) Applicant: Facebook Technologies, LLC, Menlo Park, CA (US)

(72) Inventors: Samir Mezouari, Swindon (GB); Andrea Pinos, Plymouth (GB)

(21) Appl. No.: 17/154,762

(22) Filed: Jan. 21, 2021

Related U.S. Application Data
(60) Provisional application No. 63/128,582, filed on Dec. 21, 2020.

(51) Int. Cl. H01L 33/60; H01L 27/15

(52) U.S. Cl. CPC H01L 33/60; G02B 27/0172; H01L 27/156

(57) ABSTRACT

The invention is directed towards employing semiconductor-based waveguides as secondary optical components that reduce the beam divergence of light generated by LEDs. A lighting source includes a first semiconductor die and a second semiconductor die. The first semiconductor die includes an LED. The second semiconductor die is bonded to the first semiconductor device and includes a crystalline waveguide having a first waveguide surface, a second waveguide surface, and a waveguide body. The first waveguide surface receives light from the LED. The waveguide body is comprised of a crystalline material that transmits the received light from the first waveguide surface to the second waveguide surface. The second waveguide surface emits the received portion of the light with a second beam divergence that is significantly less than the first beam divergence.

### CROSS-REFERENCE TO RELATED APPLICATIONS

This application claims the benefit of U.S. Provisional Application No. 63/128,582 filed Dec. 21, 2020 entitled “BEAM-SHAPING SECONDARY OPTICAL COMPONENTS FOR MICRO LIGHT EMITTING DIODES,” the entire contents of which are incorporated by reference herein.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-nitride semiconductors, such as alloys of AlN, GaN, InN, AlGaInP, other quaternary phosphide compositions, and the like, have begun to be developed for various display applications due to their small size (e.g., with a linear dimension less than 100 μm, less than 50 μm, less than 10 μm, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to micro light emitting diodes (micro-LEDs). More specifically, this disclosure relates to fabricating and employing crystalline waveguides as secondary optics to micro-LEDS to collimate and/or decrease the beam divergence of light emitted by the LEDs. The waveguides and LEDs may be employed in combination for a light source. According to certain embodiments, a light source may include a first semiconductor die and a second semiconductor die.

The first semiconductor die may include a first light emitting device (LED). The first LED may include a first light emitting surface (LES) that emits light (generated within the first LED) out of the first LED with a first beam divergence. The second semiconductor die may be bonded to the first semiconductor device and may include a first crystalline waveguide. The first waveguide may include a first waveguide surface, a second waveguide surface, and a waveguide body. The first waveguide surface may be configured to receive, from the first LES of the first LED, at least a portion of the light generated within the first LED. The second waveguide surface may be configured as a second LES. The waveguide body may be comprised of a transparent crystalline material that transmits light received by the first waveguide surface to the second waveguide surface. The first waveguide surface, the second waveguide surface, and the waveguide body may be configured such that the second waveguide surface emits the received portion of the light, generated within the first LED, out of the first waveguide with a second beam divergence. The second beam divergence may be significantly less than the first beam divergence.

In some embodiments, the light source is included in a wearable device that generates a virtual reality environment for a user wearing the wearable device. In other embodiments, the light source is included in a wearable device that generates an augmented reality environment for a user wearing the wearable device. The first LED may be a micro light emitting diode. A spatial dimension of the first LES of the first LED may be less than 10 micrometers. In some embodiments, the spatial dimensions of each of the first and second waveguide surfaces may be less than 5 micrometers. The first waveguide surface may be smaller than the second waveguide surface.

The transparent crystalline material may be a gallium nitride (GaN) grown on a semiconductor substrate. Each spatial dimension of each imperfection in an optical surface finish of the first waveguide may be less than 5 nanometers (nm). The first semiconductor die may include an array of LEDs that includes the first LED. The second semiconductor die may include an array of waveguides that includes the first waveguide. There may be a one-to-one correspondence between each LED of the array of LEDs and each waveguide of the array of waveguides. The first LED may uniquely correspond to the first waveguide.

In some embodiments, the array of waveguides may be formed on a continuous layer of the transparent crystalline material. A waveguide body of each waveguide of the array of waveguide may protrude from the continuous layer of the transparent crystalline material. A proximal surface of each waveguide of the array of waveguides may include a portion of the continuous layer of transparent crystalline material. A distal surface of each waveguide of the array of waveguide may be displaced from the continuous layer of the transparent crystalline material.

In other embodiments, the array of waveguides may be formed on a discontinuous layer of the transparent crystalline material. The discontinuous layer of the transparent crystalline material may include an array of separate dielectric layer portions formed via an etching process. There may be a one-to-one correspondence between each dielectric layer portion of the array of separate dielectric layer portions and each waveguide of the array of waveguides.

The waveguide body may have a tapered shape that is characterized by a tapering angle associated with a growth process of the transparent crystalline material on a semiconductor substrate. Due to the crystalline growth process and/or the tapered shape, a first surface area of the first waveguide surface may be less than a second surface area of the second waveguide surface. The waveguide body may have a mesa shape formed at least in part by removing a portion of the transparent crystalline material from the second semiconductor die via an etching process.

The first waveguide may further comprise of a reflective layer that encapsulates a portion of the waveguide body. The waveguide body may be configured to decrease a transmission loss associated with the waveguide body and decrease the beam divergence of the received portion of the light generated within the first LED. The second semiconductor die may further include a first dielectric layer that encapsulates at least a portion of the waveguide body. The first dielectric layer may cover the first waveguide surface. The second semiconductor die may further include a second dielectric layer and a layer of the transparent crystalline material. The second dielectric layer may cover the second waveguide surface. The layer of the transparent crystalline material may be interposed between the first and second dielectric layers.

The second semiconductor die may further include a non-transparent baffle structure. The baffle structure may be positioned around at least a portion of a perimeter of the second waveguide surface and extended beyond a plane of the second semiconductor die. The positioning of the baffle structure may define a columnar volume that extends beyond the plane of the second semiconductor die. The baffle structure may be configured to confine a transmission, of the light emitted by the second waveguide surface and out of the second semiconductor die, within the columnar volume extending beyond the plane of the second semiconductor die.

In some embodiments, the second waveguide surface may have a curved shaped formed at least in part by removing a portion of the transparent crystalline material from the second semiconductor die via an etching process such that the second waveguide surface's curved shape is configured to decreases the beam divergence, of the light emitted by the second waveguide surface and out of the second semiconductor die.

In at least one embodiment, a shape of the second waveguide surface is planar surface. The second semiconductor die may include a convex dielectric lens, e.g., a convex lens that comprises of and/or is fabricated from a dielectric material. In some embodiments, the dielectric material may include silicon dioxide or any other dielectric material that includes sufficient light-refracting properties. The convex dielectric lens may cover the second waveguide surface that receives the portion of light, generated within the first LED and emitted by the second waveguide surface with the second beam divergence. The convex dielectric lens may emit the received portion of light with a third beam divergence that is less than the second beam divergence. The light source may further include a transparent glass substrate bonded to the second semiconductor die and covering the second waveguide surface. The second semiconductor die may be interposed between the first semiconductor die and the glass substrate.

In some embodiments, a method of manufacturing a light source may include growing an array of crystalline waveguides on a crystalline material layer positioned on a first semiconductor wafer. A metallization layer may be deposited and/or formed on at least a portion of the crystalline material. The metallization layer may provide optical isolation of each waveguide in the array of crystalline waveguides from each of the other waveguides in the array of waveguides. The array of crystalline waveguides may be physically removed from the first semiconductor wafer. The array of waveguides may be bonded to an array of light emitting devices (LEDs). There may be a one-to-one correspondence between each waveguide of the array of crystalline waves guides and each LED of the arrays of LEDS. Each waveguide of the array of crystalline waveguides may be configured to decrease a beam divergence of light emitted from the corresponding LED.

Another method for manufacturing a light source includes growing an array of three-dimensional (3D) crystalline structures on a crystalline material layer. The crystalline material layer may be positioned on a first semiconductor wafer. The array of 3D crystalline structures may be employed to fabricate an imprinting and/or embossing tool. The imprinting tool may have a complementary shape to the shape of the array of 3D crystalline structures. In some embodiments, the imprinting tool is a soft imprinting and/or embossing tool. In other embodiments, the imprinting tool is a hard imprinting and/or embossing tool. The imprinting tool may be employed to form an array of waveguides. The array of waveguides may be bonded to an array of light emitting devices (LEDs) to form the light source. The array of waveguides may be configured to decrease a beam divergence of light emitted from the arrays of LEDs

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIG. 8A illustrates an example of a method of die-to-wafer bonding for arrays of LEDs according to certain embodiments.

FIG. 8B illustrates an example of a method of wafer-to-wafer bonding for arrays of LEDs according to certain embodiments.

FIGS. 9A-9D illustrates an example of a method of hybrid bonding for arrays of LEDs according to certain embodiments.

FIG. 10 illustrates an example of an LED array with secondary optical components fabricated thereon according to certain embodiments.

FIG. 11A illustrates an example angular distribution of light emitted by a Lambertian-like light emitting device, according to certain embodiments.

FIG. 11B illustrates cross-sectional view of a light source that includes an array of waveguides as beam-collimating secondary optical components for an array of light emitting devices, according to some embodiments.

FIG. 11C illustrates an example angular distribution of light emitted by a Lambertian-like light emitting device employing a waveguide as a secondary optical component, according to certain embodiments.

FIG. 12A illustrates a semiconductor process for fabricating the array of waveguides of FIG. 11B, according to certain embodiments.

FIG. 12B illustrates a method for manufacturing the light source of FIG. 11B, according to certain embodiments.

FIG. 13 illustrates an embodiment for an array of high-fill factor waveguides.

FIG. 14A illustrates a semiconductor process for fabricating the array of high-fill factor waveguides of FIG. 13, according to certain embodiments.

FIG. 14B illustrates a method for manufacturing the high-fill factor waveguide array of FIG. 13, according to certain embodiments.

FIG. 15 illustrates an embodiment for an array of crystalline baffled waveguides.

FIG. 16A illustrates a semiconductor process for fabricating the array of baffled waveguides of FIG. 15, according to certain embodiments.

FIG. 16B illustrates a method for manufacturing the baffled waveguide array of FIG. 15, according to certain embodiments.

FIG. 17A illustrates a semiconductor process for fabricating a soft embossing tool for embossing a waveguide array in a non-crystalline material, according to certain embodiments.

FIG. 17B illustrates a method for manufacturing the soft imprinting tool of FIG. 17A, according to certain embodiments.

FIG. 18A illustrates a semiconductor process for fabricating a hard embossing tool 1800 for embossing a waveguide array in a non-crystalline material, according to certain embodiments.

FIG. 18B illustrates a method for manufacturing the hard imprinting tool of FIG. 18A, according to certain embodiments.

FIG. 19 is a simplified block diagram of an electronic system of an example of a near-eye display according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to light emitting diodes (LEDs). More specifically, and without limitation, disclosed herein are techniques for fabricating and employing semiconductor-based optical waveguides as secondary optical components for light emitting diodes (LEDS) and/or micro-LEDs (μLEDs).

Given their small size and mass, as well as their low power requirements, μLEDs are good candidates for light sources in various devices, such as but not limited to mobile devices with pixel-based displays and wearable devices with head-mounted and/or near-eye displays. However, the light generated by a μLED may not be directly employable as a light source for some applications and/or devices. At least because the angular distribution of light generated by a μLED is relatively wide and/or dispersed, the light generated by the μLED may be too diffuse for direct employment as a light source for devices and/or applications that require light with a relatively small and/or well defined beam spot. That is, a light beam generated and emitted by a pLED may be relatively divergent and/or uncollimated, such that the divergent light beam is not employable as a light source for a display in a device and/or application. For example, a typical μLED may radiate a light beam with a beam profile that is approximated by Lambert's cosine law. The angular distribution of the intensity of a Lambertian-like beam may be approximately proportional to cos θ, where θ is the angle as measured from a vector that is normal to the LED's light emitting surface (LES). The angular distribution (or beam divergence) of a light beam emitted by such Lambertian-like LEDs may be characterized by a full width at half maximum (FWHM) of approximately 120°,

$$( i . e . , {cos}^{- 1} ( \frac{1}{2} ) = \frac{π}{3} ) .$$

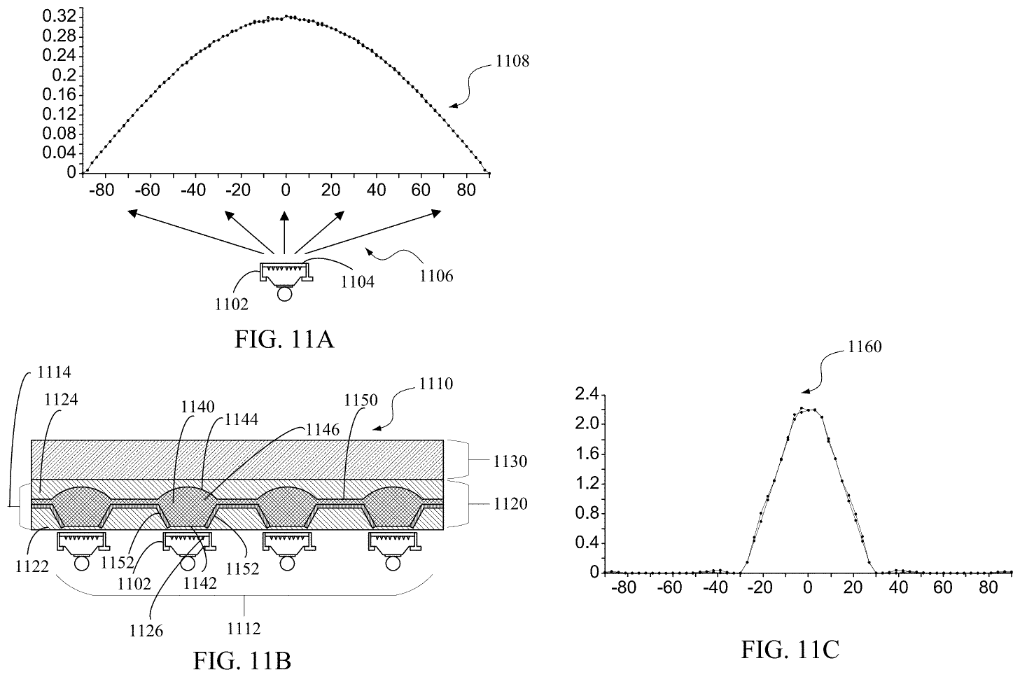

For an example of a Lambertian-like beam divergence, see angular distribution 1108 of FIG. 11A.

A Lambertian distribution of light may be too diffuse for many applications, such as those that employ μLEDs as light sources for one or more pixels in a display. For instance, some applications may require a significant portion of the LED's optical output (e.g., 80% of the beam's intensity or power) to fall within a cone of emittance, with a relatively small opening angle and/or emittance angle (e.g.,)20°. As such, technologists have contemplated employing conventional beam-shaping techniques to collimate (or reduce the beam divergence) of the μLED's beam profile.

Such conventional beam-shaping (e.g., beam collimation) techniques for light generated by μLEDs include employing a lens (e.g., a micro-lens) as a secondary optical component that acts to decrease the divergence of the beam. However, conventional micro-lenses may not sufficiently decrease the beam's divergence. Consequently, even after passing through a conventional micro-lens, a significant proportion of a μLED's light beam may still be distributed outside the desired emittance cone, with respect to various applications employing a μLED as a light source. Micro-lenses are conventionally fabricated via imprinting and/or embossing processes (e.g., nanoimprint lithography processes) performed on amorphous (or non-crystalline) materials (e.g., fused silica). Conventional nanoimprinting lithography may require the use of expensive “hard” embossing tools. In addition to the tools' significant costs, the surface finish of conventionally fabricated hard embossing tools may not be of sufficient quality to emboss micro-lenses of the size required to reduce the beam divergence of μLEDs. Due to the small surface area of a light emitting surface of a μLED, the surface area of a micro-lens required to collimate the beam may be on the order of a few square microns. Reliably fabricating hard imprinting tools with features of physical size on the order of a few microns is difficult and expensive. Sufficiently collimating the beam and/or reducing the beam divergence of such a micro-lens may require any imperfections on the surface finish of the lens to be less than approximately 5 nanometers. Conventional methods of fabricating hard tools may not reliably yield such small feature sizes and/or sufficiently smooth surface finishes. If the feature size of the micro-lens is not small enough, or if relatively large (e.g., >5 nanometers) imperfections exist in the surface finish of the embossing tools, the micro-lens may fail to sufficiently decrease the beam divergence. For many applications, a micro-lens fabricated via a hard embossing tool or other conventional methods may not sufficiently decrease the beam divergence of light emitted by a μLED.

As such, and in contrast to conventional micro-lens based approaches, the various herein embodiments are directed towards fabricating and employing semiconductor-based waveguides as secondary optical components to reduce the beam divergence of light generated by LEDs and μLEDs. For example, beam-shaping secondary optical components (e.g., any of the waveguides discussed herein) may be employed to shape the beam profile (e.g., reduce the beam's divergence) of light generated by μLEDs. Thus, beam-shaping optical elements may be utilized to employ μLEDs in applications that require well-collimated light and/or less diffuse optical intensity and/or power distributions.

More specifically, in the various embodiments non-conventional and novel semiconductor-based waveguide structures (e.g., enhanced waveguides fabricated from crystalline semiconductor material) are employed as secondary optical components for μLEDs. The semiconductor-based waveguides act to collimate and/or reduce the beam divergence of the light generated by LEDs and/or μLEDs. Reducing the beam divergence may increase the optical power density of an LED's beam sufficiently to employ the LED in various applications that require highly collimated light and/or tightly controlled beam profiles (e.g., light beams with a relatively small divergence and/or well defined beam spot). Various inventive embodiments are described herein, which are directed towards the fabrication and utilization of semiconductor-based waveguides as secondary optical components for LEDs. The various embodiments include devices, systems, methods, materials, imprinting/embossing tools, and the like.

In some embodiments, a μLED may emit a beam characterized by a first beam divergence (e.g., see FIG. 11A for an illustration of a Lambertian-like beam with a FWHM of approximately 120°). When an enhanced waveguide is employed as a secondary optical component for the LED, the beam (after passing through the waveguide) may be characterized by a second beam divergence that is significantly less than the first beam divergence. For instance, the second beam divergence may be such that approximately 80% of the beam's power or intensity is confined to an emittance cone of approximately 20°. Without the employment of the enhanced waveguide, approximately only 11% of the first beam divergence would fall within such an emittance cone. For an example of a reduced beam divergence via a waveguide as a secondary optical component, see angular distribution 1160 of FIG. 11C. The significant reduction in beam divergence is demonstrated via a visual comparison between the first beam divergence (e.g., angular distribution 1108 of FIG. 11A) and the second beam divergence (e.g., angular distribution 1160 of FIG. 11C). With an optical coupling efficiency (between the μLED and waveguide) of around 70%, employment of the waveguide may result in a transmission gain of at least 5 times beyond that of the use of the μLED without the waveguide. For example, as noted above, without the waveguide present, approximately 11% of the light is confined within an emittance cone of 20° , while with the waveguide, the overall efficiency (within the desired emittance cone) is around 0.7×0.8=0.56.

In various embodiments, a waveguide structure may be fabricated from a semiconductor material, such as but not limited to gallium nitride (GaN). To fabricate the waveguide, a layer of semiconductor material may be deposited on a semiconductor substrate (e.g., a semiconductor wafer) formed of a separate semiconductor material. The semiconductor material of the waveguide structure may be a material that grows crystalline structures. Via crystal growth, a crystalline structure may be grown on the deposited layer of the semiconductor material. In crystalline form, the semiconductor material may be relatively transparent to the frequencies of light emitted by a μLED. Due to the optical properties of the crystalline material (e.g., its index of refraction relative to the index of refraction outside the crystalline material), the crystalline structure may adequately confine and transmit received light and act as a waveguide for frequencies characteristic of the μLED.

That is, due to the optical properties and the shape of the waveguide, the sidewall surfaces (e.g., those surfaces of the waveguide's body that are generally aligned with the direction of the beam's transmission) of the waveguide may provide significant internal reflection for light within the waveguide. Furthermore, due to the nature of growing the crystalline structures on the semiconductor substrate, the waveguide structure may include a tapered shape. At least due to the tapered shape, which occurs due to process of growing the crystalline structures, the waveguide structure may act to decrease the beam divergence of the received light, as well as increase the internal reflection of the waveguide' s sidewalls. Thus, the waveguide structure may act as a focusing and/or collimating waveguide that shapes a beam of received light. Furthermore, at least a shape of the exiting surface of the waveguide (e.g., the waveguide surface that emits the light beam after the light passes through the waveguide body) may be formed (e.g., via an etching process) to include lensing (or beam shaping) effects that further increase the focusing and/or collimating power of the waveguide. For example, the outgoing surface of the waveguide may be etched and/or polished into a surface that is shaped similarly to a spherical and/or convex lens.

In some embodiments, one or more μLEDs (e.g., a 1D or 2D array of μLEDs), or an array of another such light emitting device, may be fabricated on and/or bonded to a first semiconductor die. One or more waveguides (a corresponding 1D or 2D array of waveguides) maybe fabricated on a second semiconductor die. The first and second semiconductor dice may be bonded, such that each μLED is aligned with a corresponding waveguide (e.g., there is a one-to-one correspondence between the μLEDs and waveguides of the respective semiconductor dice). An LED of the array of LEDs may include a light emitting surface (LES) that emits at least a portion of the light generated within the active region of the LED. The light emitted by the LED's LES may have a first beam divergence, as measured by the beam's angular distribution. For example, the first beam divergence may be Lamb ertian-like and characterized as having a FWHM of approximately 120°.

When bonding the first and second semiconductor dice, the dice may be aligned such that each LED of the LED array is aligned with its corresponding waveguide of the waveguide array. A waveguide may include a first waveguide surface, a second waveguide surface, and a waveguide body, as well as sidewalls of the body. The first waveguide surface may be aligned proximate to the LES of the LED, such that the first waveguide surface receives the light emitted by the LED's LES, e.g., the LED's light is incident on the first waveguide surface and enters a spatial volume defined by the waveguide's body. In some embodiments, the first waveguide surface is generally a planar surface. The direction of the beam's transmission may be generally orthogonal to a plane of the first waveguide surface. Thus, the first waveguide surface may be configured as a light receiving surface that acts as an entrance (into the spatial volume defined by the waveguide body) for the LED's light, or other light incident on the first waveguide surface. The spatial volume defined by the waveguide body may be filled with the crystalline material. Due to the significant internal reflection of the waveguide, the crystalline material (and thus the waveguide body) may transmit, at least a significant portion of, the received light from the first waveguide surface to the second waveguide surface, e.g., there is little optical absorption or light leakage with the waveguide body.

The second waveguide surface may be configured to emit the light (e.g., light transmitted from the first waveguide surface to the second waveguide surface, via the waveguide body) out of the waveguide body and into the waveguide' s ambient environment. That is, the second waveguide surface may be configured as a light exiting surface and/or light emitting surface for the waveguide. The shape of the waveguide body and/or the shape of the second waveguide surface may act to significantly collimate the beam and/or to significantly decrease the beam's divergence. Furthermore, due to the waveguide's optical transmission efficiency (e.g., the waveguide's optical transparency) and its significant optical internal reflection characteristics, the beam experiences insignificant optical power loss as the beam's angular divergence is decreased via its traversal through the waveguide.

As noted above, the beam may enter the waveguide with a first beam divergence, via the first waveguide surface. The beam may exit the waveguide, via the second waveguide surface, with a second beam divergence that is significantly less than the first beam divergences. For example, the first beam divergences may be characterized with a FWHM of approximately 120°. The second beam divergence may be characterized such that approximately 80% of the beam is contained within an emittance cone of an opening angle of approximately 20°. Thus, the waveguide may act as a secondary optical component that collimates, or at least significantly reduces the beam divergence of the LED's light.

Some embodiments may be “high-fill factor” embodiments, with an increased aspect ratio of the waveguide body. The increased aspect ratio may provide increases to the collimation and/or divergence reduction capabilities of the waveguides. Various embodiments may include a “baffle” structure that optically isolates adjacent waveguides and provides still greater collimation and/or divergence reduction capabilities of the waveguides. Still other embodiments may additionally and/or alternatively include dielectric “lensing” structures that act as a secondary optical component to the waveguide (or a tertiary optical component to the LED). Such dielectric lens structure may provide even greater collimation and/or divergence reduction capabilities of the waveguides. Some embodiments include employing the crystalline waveguide growth process to fabricate “soft” or “hard” imprinting or embossing tools in the form of the waveguide array. Such imprinting tools maybe employed to fabricate similarly shaped waveguide structures in other materials. Thus, the waveguide discussed herein may be fabricated via other methods (e.g., imprinting or embossing) and/or other waveguide materials.

Employing the waveguides as a secondary optical component to reduce the beam divergence of the light emitted by the LED has several advantages over the use of conventional micro-lenses employed to focus the light from an LED. For many applications where a conventional micro-lens may not sufficiently reduce the beam divergence, the beam-shaping properties of the enhanced waveguides may reduce the beam divergence significantly and enable employment in the applications. Thus, when employed as a secondary optical component for a μLED, the waveguides discussed herein may enable the employment of the μLED in applications where a micro-lens may be deficient as a beam collimator. That is, after passing through the waveguide, the divergence of the μLED's beam may be small enough to employ in various applications, where a conventional micro-lens based approach fails to sufficiently decrease the beam's divergence. Thus, the combination of pLED and an enhanced waveguide may be employed as a light source in many applications that require a light beam with a relatively low beam divergence.

As noted above, fabricating conventional micro-lenses may require the use of relatively expensive “hard” imprinting or embossing tools. In contrast to embossing-based fabrication, the waveguides discussed herein are formed via semiconductor fabricating processes. Such processes include but are not limited to growing the waveguide's crystalline structure on a wafer, depositing oxide and/or metallization layers on portions of the wafer (e.g., via lithography processes), and etching surfaces of the wafer and/or waveguides (e.g., via etching processes). Such semiconductor processes do not require expensive imprinting tools. As noted above, the surface of conventional imprinting tools may not be sufficiently smooth to precisely and uniformly imprint micro-lenses with feature sizes on the order of a few microns. For example, imperfections on the imprinting surface of an imprinting tool may be larger than 5 nm, and the resulting micro-lenses may not sufficiently collimate the light for some applications. That is, the surface imperfections in conventional imprinting tools may result in micro-lenses that provide significant scattering and/or dispersion of the light beam to be collimated. Accordingly, the various waveguide embodiments discussed herein may provide significantly more collimation and/or decrease in the beam's divergences, compared to employing micro-lenses.

Rather than employing expensive and/or insufficiently “smooth” (e.g., free of surface imperfections larger than a feature size threshold) imprinting tools, fabricating the waveguides discussed herein includes growing crystalline structures that comprise the crystalline bodies of the waveguides. The crystalline growth process may be such that crystalline structures grown on a wafer (e.g., a semiconductor substrate) are extremely uniform (in shape and crystal structure) across the wafer. As noted above, the waveguide body may include a tapered shaped (e.g., a truncated pyramid and/or mesa structure), wherein due to the crystal growth process, the tapered shape of waveguides across the wafer is extremely uniform. The precise shape and uniformity of the waveguides may result in precise and uniform optical properties, leading to significant and uniform decreases of beam divergence for the waveguides fabricated across the wafer. When compared to employing conventional micro-lenses to collimate an LED's beam, the embodiments employing waveguides as secondary optical components may provide significantly more decrease in the beam's divergence and may be significantly less expensive to manufacture.

The micro-LEDs and waveguides described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

As used herein, the term “light emitting diode (LED)” refers to a light source that includes at least an n-type semiconductor layer, a p-type semiconductor layer, and a light emitting region (i.e., active region) between the n-type semiconductor layer and the p-type semiconductor layer. The light emitting region may include one or more semiconductor layers that form one or more heterostructures, such as quantum wells. In some embodiments, the light emitting region may include multiple semiconductor layers that form one or more multiple-quantum-wells (MQWs), each including multiple (e.g., about 2 to 6) quantum wells.

As used herein, the term “micro-LED” or “μLED” refers to an LED that has a chip where a linear dimension of the chip is less than about 200 μm, such as less than 100 μm, less than 50 p.m, less than 20 μm, less than 10 μm, or smaller. For example, the linear dimension of a micro-LED may be as small as 6 μm, 5 μm, 4 μm, 2 μm, or smaller. Some micro-LEDs may have a linear dimension (e.g., length or diameter) comparable to the minority carrier diffusion length. However, the disclosure herein is not limited to micro-LEDs, and may also be applied to mini-LEDs and large LEDs.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, soldering, under-bump metallization, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher. As used herein, the term “bump” may refer generically to a metal interconnect used or formed during bonding.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

### Micro-LEDS Employed as a Light Source

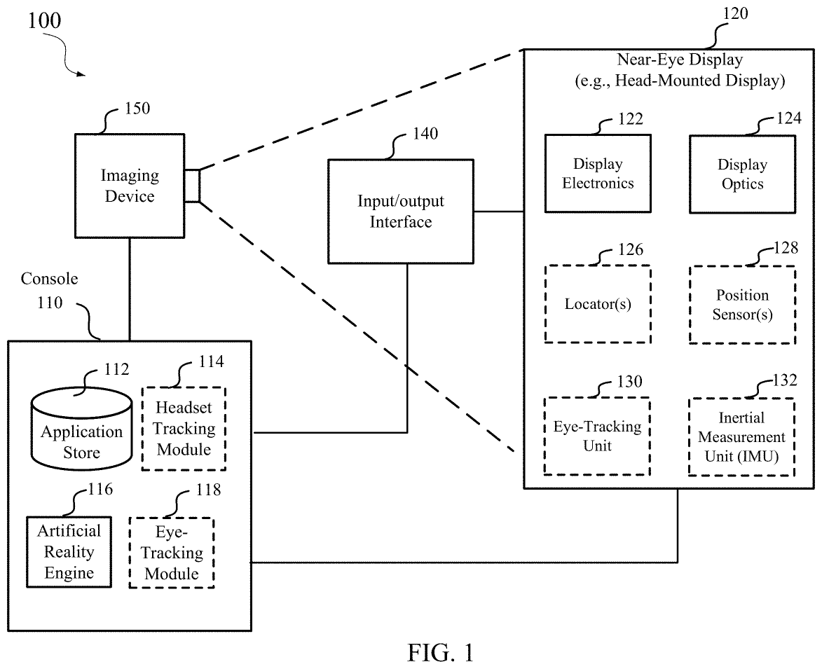

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

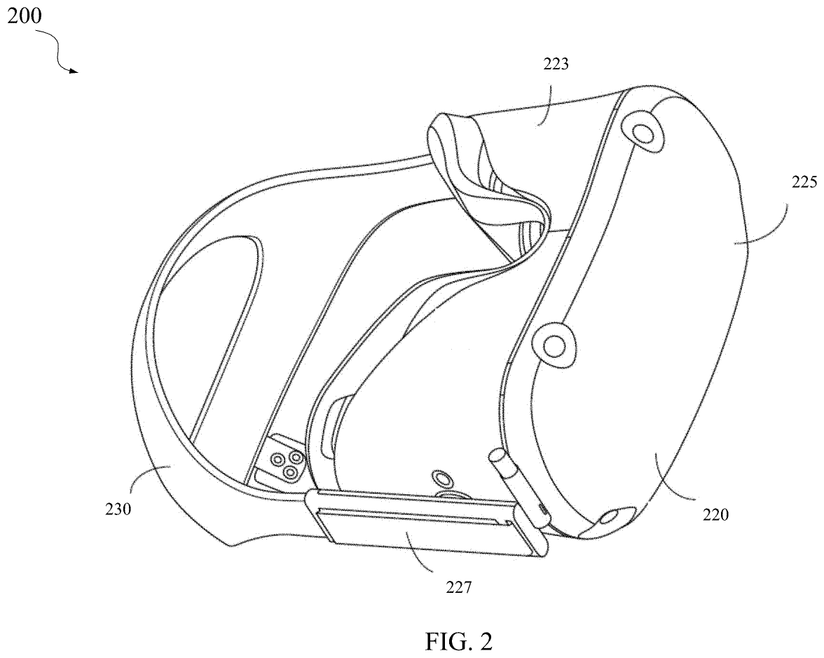

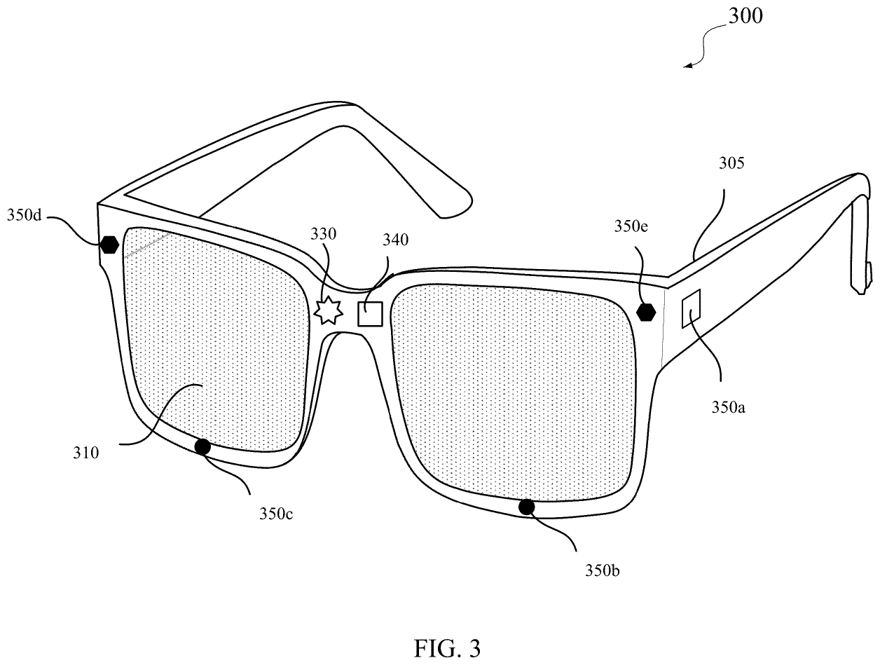

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HIVID device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

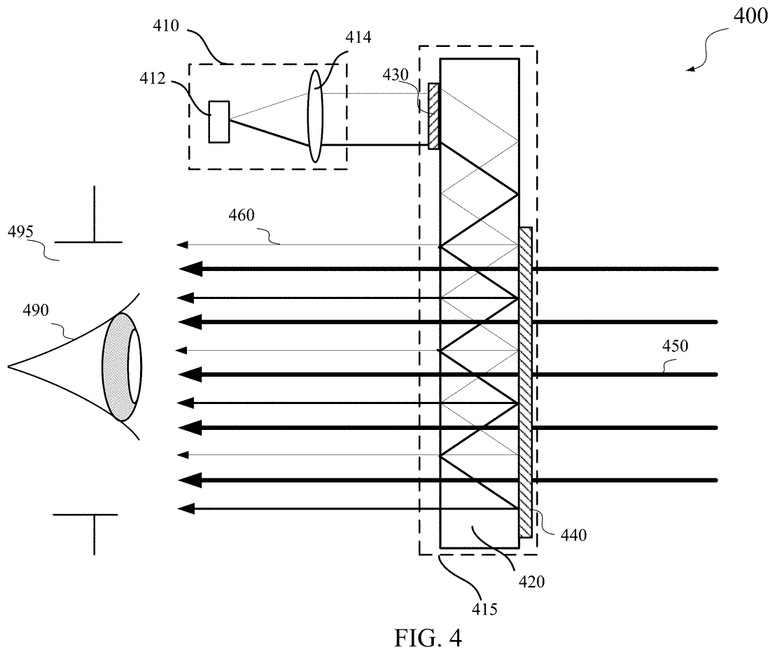

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

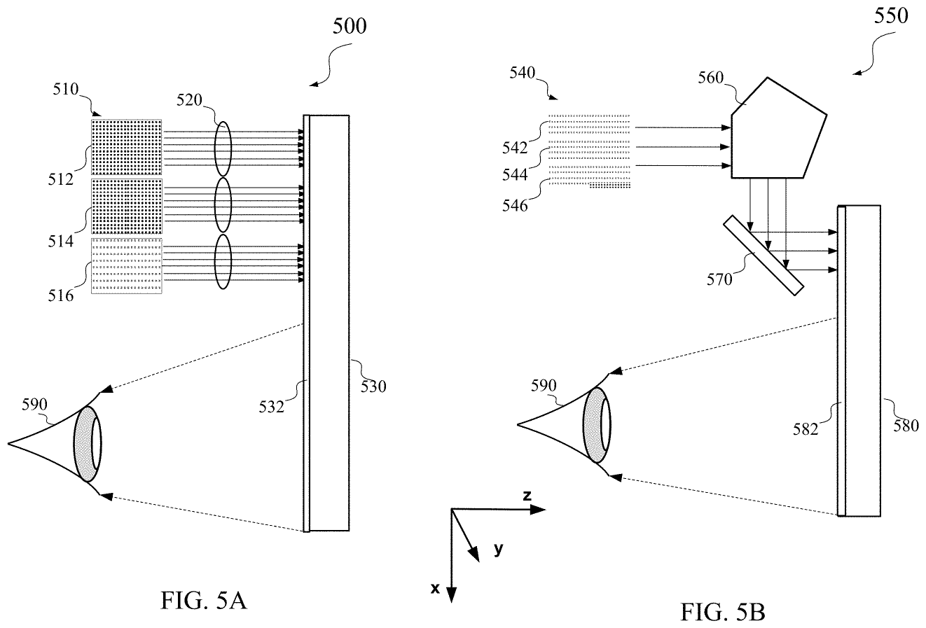

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

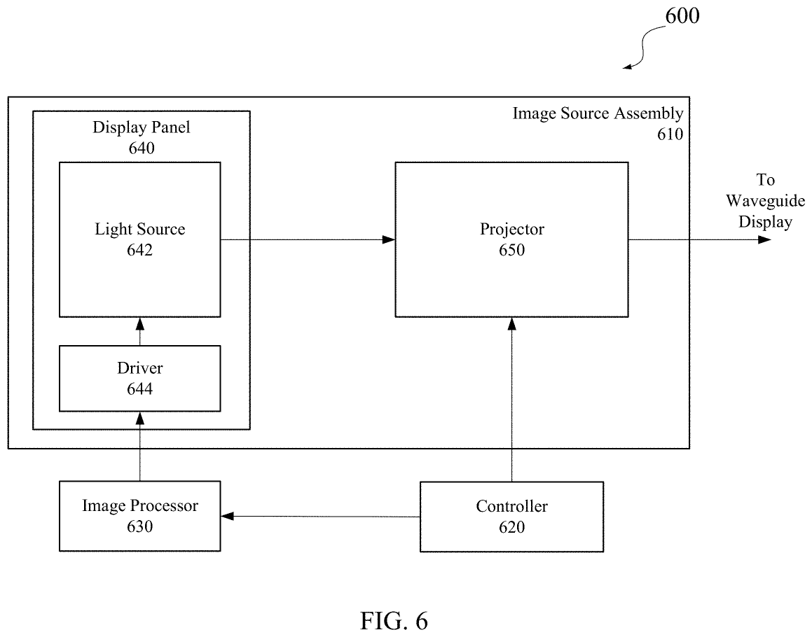

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a driver circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and driver circuit 644, image processor 630 may be a sub-unit of controller 620 or driver circuit 644 in other embodiments. In other words, in those embodiments, controller 620 or driver circuit 644 may perform various image processing functions of image processor 630. Image processor 630 may also be referred to as an image processing circuit.

In the example shown in FIG. 6, light source 642 may be driven by driver circuit 644, based on data or instructions (e.g., display and scanning instructions) sent from controller 620 or image processor 630. In one embodiment, driver circuit 644 may include a circuit panel that connects to and mechanically holds various light emitters of light source 642. Light source 642 may emit light in accordance with one or more illumination parameters that are set by the controller 620 and potentially adjusted by image processor 630 and driver circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

In semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device.

The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency and/or controlling the emission spectrum may be challenging. In some embodiments, to increase the light extraction efficiency, a mesa that includes at least some of the layers of semiconductor materials may be formed.

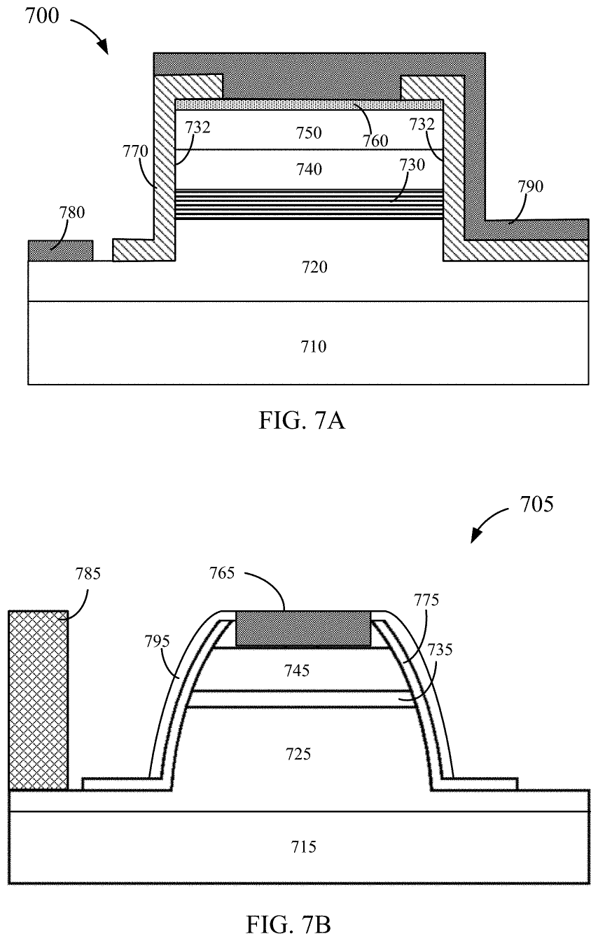

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiNx) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

One or two-dimensional arrays of the LEDs described above may be manufactured on a wafer to form light sources (e.g., light source 642). Driver circuits (e.g., driver circuit 644) may be fabricated, for example, on a silicon wafer using CMOS processes. The LEDs and the driver circuits on wafers may be diced and then bonded together, or may be bonded on the wafer level and then diced. Various bonding techniques can be used for bonding the LEDs and the driver circuits, such as adhesive bonding, metal-to-metal bonding, metal oxide bonding, wafer-to-wafer bonding, die-to-wafer bonding, hybrid bonding, and the like.

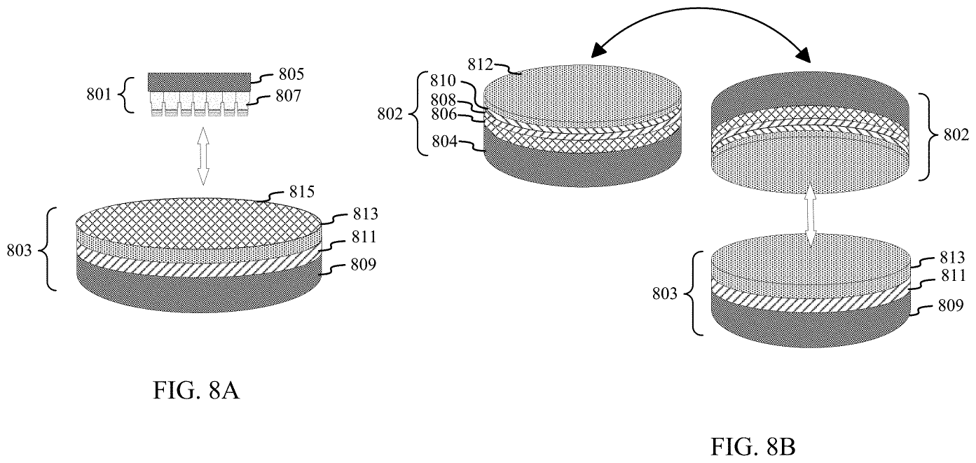

FIG. 8A illustrates an example of a method of die-to-wafer bonding for arrays of LEDs according to certain embodiments. In the example shown in FIG. 8A, an LED array 801 may include a plurality of LEDs 807 on a carrier substrate 805. Carrier substrate 805 may include various materials, such as GaAs, InP, GaN, A1N, sapphire, SiC, Si, or the like. LEDs 807 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (AlGaIn)Pas, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 803 may include a base layer 809 having passive or active integrated circuits (e.g., driver circuits 811) fabricated thereon. Base layer 809 may include, for example, a silicon wafer. Driver circuits 811 may be used to control the operations of LEDs 807. For example, the driver circuit for each LED 807 may include a 2T1C pixel structure that has two transistors and one capacitor. Wafer 803 may also include a bonding layer 813. Bonding layer 813 may include various materials, such as a metal, an oxide, a dielectric, CuSn, AuTi, and the like. In some embodiments, a patterned layer 815 may be formed on a surface of bonding layer 813, where patterned layer 815 may include a metallic grid made of a conductive material, such as Cu, Ag, Au, Al, or the like.

LED array 801 may be bonded to wafer 803 via bonding layer 813 or patterned layer 815. For example, patterned layer 815 may include metal pads or bumps made of various materials, such as CuSn, AuSn, or nanoporous Au, that may be used to align LEDs 807 of LED array 801 with corresponding driver circuits 811 on wafer 803. In one example, LED array 801 may be brought toward wafer 803 until LEDs 807 come into contact with respective metal pads or bumps corresponding to driver circuits 811. Some or all of LEDs 807 may be aligned with driver circuits 811, and may then be bonded to wafer 803 via patterned layer 815 by various bonding techniques, such as metal-to-metal bonding. After LEDs 807 have been bonded to wafer 803, carrier substrate 805 may be removed from LEDs 807.

FIG. 8B illustrates an example of a method of wafer-to-wafer bonding for arrays of LEDs according to certain embodiments. As shown in FIG. 8B, a first wafer 802 may include a substrate 804, a first semiconductor layer 806, active layers 808, and a second semiconductor layer 810. Substrate 804 may include various materials, such as GaAs, InP, GaN, A1N, sapphire, SiC, Si, or the like. First semiconductor layer 806, active layers 808, and second semiconductor layer 810 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 806 may be an n-type layer, and second semiconductor layer 810 may be a p-type layer. For example, first semiconductor layer 806 may be an n-doped GaN layer (e.g., doped with Si or Ge), and second semiconductor layer 810 may be a p-doped GaN layer (e.g., doped with Mg, Ca, Zn, or Be). Active layers 808 may include, for example, one or more GaN layers, one or more InGaN layers, one or more AlInGaP layers, and the like, which may form one or more heterostructures, such as one or more quantum wells or MQWs.

In some embodiments, first wafer 802 may also include a bonding layer. Bonding layer 812 may include various materials, such as a metal, an oxide, a dielectric, CuSn, AuTi, or the like. In one example, bonding layer 812 may include p-contacts and/or n-contacts (not shown). In some embodiments, other layers may also be included on first wafer 802, such as a buffer layer between substrate 804 and first semiconductor layer 806. The buffer layer may include various materials, such as polycrystalline GaN or A1N. In some embodiments, a contact layer may be between second semiconductor layer 810 and bonding layer 812. The contact layer may include any suitable material for providing an electrical contact to second semiconductor layer 810 and/or first semiconductor layer 806.

First wafer 802 may be bonded to wafer 803 that includes driver circuits 811 and bonding layer 813 as described above, via bonding layer 813 and/or bonding layer 812. Bonding layer 812 and bonding layer 813 may be made of the same material or different materials. Bonding layer 813 and bonding layer 812 may be substantially flat. First wafer 802 may be bonded to wafer 803 by various methods, such as metal-to-metal bonding, eutectic bonding, metal oxide bonding, anodic bonding, thermo-compression bonding, ultraviolet (UV) bonding, and/or fusion bonding.

As shown in FIG. 8B, first wafer 802 may be bonded to wafer 803 with the p-side (e.g., second semiconductor layer 810) of first wafer 802 facing down (i.e., toward wafer 803). After bonding, substrate 804 may be removed from first wafer 802, and first wafer 802 may then be processed from the n-side. The processing may include, for example, the formation of certain mesa shapes for individual LEDs, as well as the formation of optical components corresponding to the individual LEDs.

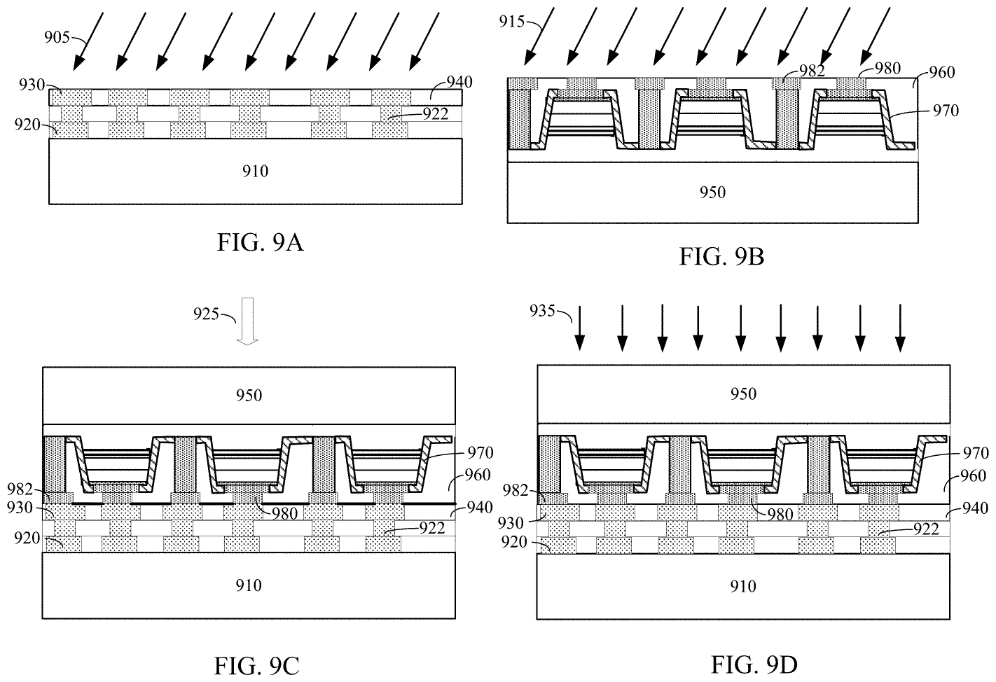

FIGS. 9A-9D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 9A shows a substrate 910 with passive or active circuits 920 manufactured thereon. As described above with respect to FIGS. 8A-8B, substrate 910 may include, for example, a silicon wafer. Circuits 920 may include driver circuits for the arrays of LEDs. A bonding layer may include dielectric regions 940 and contact pads 930 connected to circuits 920 through electrical interconnects 922. Contact pads 930 may include, for example, Cu, Ag, Au, Al, W, Mo, Ni, Ti, Pt, Pd, or the like. Dielectric materials in dielectric regions 940 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 905. The activated surface may be atomically clean and may be reactive for formation of direct bonds between wafers when they are brought into contact, for example, at room temperature.

FIG. 9B illustrates a wafer 950 including an array of micro-LEDs 970 fabricated thereon as described above with respect to, for example, FIGS. 7A-8B. Wafer 950 may be a carrier wafer and may include, for example, GaAs, InP, GaN, A1N, sapphire, SiC, Si, or the like. Micro-LEDs 970 may include an n-type layer, an active region, and a p-type layer epitaxially grown on wafer 950. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 980 and n-contacts 982 may be formed in a dielectric material layer 960 deposited on the mesa structures and may make electrical contacts with the p-type layer and the n-type layers, respectively. Dielectric materials in dielectric material layer 960 may include, for example, SiCN, Sift, SiN, Al₂O₃, HfO₂, ZrO₂, Ta₂O₅, or the like. P-contacts 980 and n-contacts 982 may include, for example, Cu, Ag, Au, Al, W, Mo, Ni, Ti, Pt, Pd, or the like. The top surfaces of p-contacts 980, n-contacts 982, and dielectric material layer 960 may form a bonding layer. The bonding layer may be planarized and polished using, for example, chemical mechanical polishing, where the polishing may cause dishing in p-contacts 980 and n-contacts 982. The bonding layer may then be cleaned and activated by, for example, an ion (e.g., plasma) or fast atom (e.g., Ar) beam 915. The activated surface may be atomically clean and reactive for formation of direct bonds between wafers when they are brought into contact, for example, at room temperature.

FIG. 9C illustrates a room temperature bonding process for bonding the dielectric materials in the bonding layers. For example, after the bonding layer that includes dielectric regions 940 and contact pads 930 and the bonding layer that includes p-contacts 980, n-contacts 982, and dielectric material layer 960 are surface activated, wafer 950 and micro-LEDs 970 may be turned upside down and brought into contact with substrate 910 and the circuits formed thereon. In some embodiments, compression pressure 925 may be applied to substrate 910 and wafer 950 such that the bonding layers are pressed against each other. Due to the surface activation and the dishing in the contacts, dielectric regions 940 and dielectric material layer 960 may be in direct contact because of the surface attractive force, and may react and form chemical bonds between them because the surface atoms may have dangling bonds and may be in unstable energy states after the activation. Thus, the dielectric materials in dielectric regions 940 and dielectric material layer 960 may be bonded together with or without heat treatment or pressure.

FIG. 9D illustrates an annealing process for bonding the contacts in the bonding layers after bonding the dielectric materials in the bonding layers. For example, contact pads 930 and p-contacts 980 or n-contacts 982 may be bonded together by annealing at, for example, about 200-400° C. or higher. During the annealing process, heat 935 may cause the contacts to expand more than the dielectric materials (due to different coefficients of thermal expansion), and thus may close the dishing gaps between the contacts such that contact pads 930 and p-contacts 980 or n-contacts 982 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the driver circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

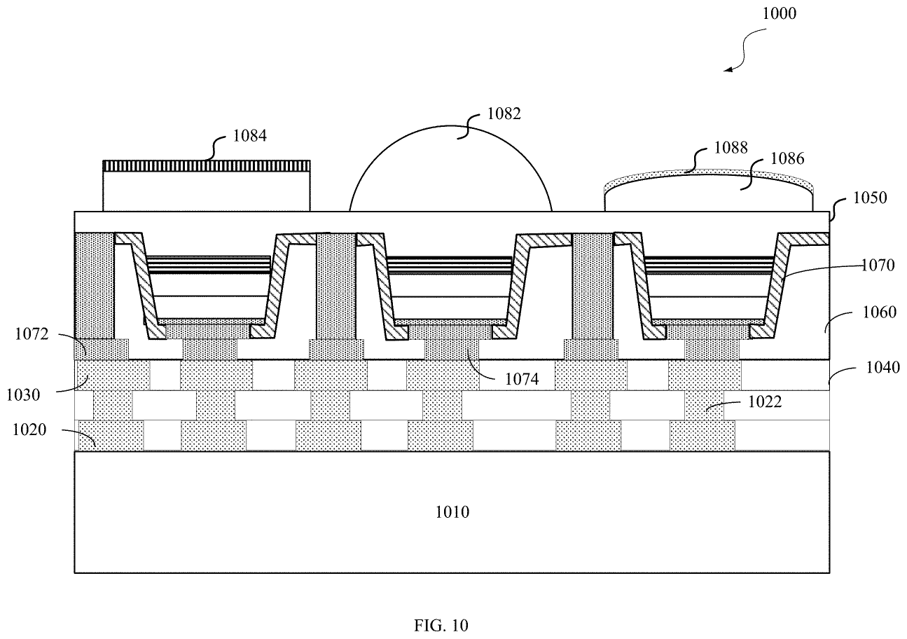

FIG. 10 illustrates an example of an LED array 1000 with secondary optical components fabricated thereon according to certain embodiments. LED array 1000 may be made by bonding an LED chip or wafer with a silicon wafer including electrical circuits fabricated thereon, using any suitable bonding techniques described above with respect to, for example, FIGS. 8A-9D. In the example shown in FIG. 10, LED array 1000 may be bonded using a wafer-to-wafer hybrid bonding technique as described above with respect to FIG. 9A-9D. LED array 1000 may include a substrate 1010, which may be, for example, a silicon wafer. Integrated circuits 1020, such as LED driver circuits, may be fabricated on substrate 1010. Integrated circuits 1020 may be connected to p-contacts 1074 and n-contacts 1072 of micro-LEDs 1070 through interconnects 1022 and contact pads 1030, where contact pads 1030 may form metallic bonds with p-contacts 1074 and n-contacts 1072. Dielectric layer 1040 on substrate 1010 may be bonded to dielectric layer 1060 through fusion bonding.

The substrate (not shown) of the LED chip or wafer may be thinned or may be removed to expose the n-type layer 1050 of micro-LEDs 1070. Various secondary optical components, such as a spherical micro-lens 1082, a grating 1084, a micro-lens 1086, an antireflection layer 1088, and the like, may be formed in or on top of n-type layer 1050. For example, spherical micro-lens arrays may be etched in the semiconductor materials of micro-LEDs 1070 using a gray-scale mask and a photoresist with a linear response to exposure light, or using an etch mask formed by thermal reflowing of a patterned photoresist layer. The secondary optical components may also be etched in a dielectric layer deposited on n-type layer 1050 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO2, SiN, A1203, HfO2, ZrO2, Ta2O5, or the like. In some embodiments, a micro-LED 1070 may have multiple corresponding secondary optical components, such as a micro-lens and an anti-reflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 10 to show some examples of secondary optical components that can be formed on micro-LEDs 1070, which does not necessary imply that different secondary optical components are used simultaneously for every LED array.

### Crystalline Waveguides Employed to Reduce Beam Divergence of Light Generated by LEDs

In addition to and/or alternatively to the secondary optical components discussed in conjunction with FIG. 10, semiconductor-based waveguides may be employed as secondary optical components in some embodiments. As noted above, a light beam emitted by an LED may be too divergent and/or diffuse to employ in many applications (e.g., as a light source in a head-mounted display, a near-eye display, a head-up display, and the like). For instance, LEDs that emit a light beam with a Lambertian-like angular distribution may not be directly employable without some secondary optical components that collimate and/or reduce the beam's divergence. The waveguides discussed herein may be employed, as secondary optical components, to shape the LED's light beam (e.g., collimate and/or reduce the beam's divergence). When the waveguides are employed as secondary optical components, such Lambertian-like LEDs may be employable in applications that require a relatively collimated light source and/or a light beam with a narrow beam profile (e.g., a beam with a small beam divergence).

FIG. 11A illustrates an example angular distribution 1108 of light 1106 emitted by a Lambertian-like light emitting device 1102, according to certain embodiments. Light emitting device 1102 may be an LED, such as any LED discussed herein, including but not limited to LED 700 of FIG. 7A, LED 705 of FIG. 7B, and/or LED 1070 of FIG. 10. LED 1102 may be a micro light emitting diode (μLED). As such, LED 1102 may include a light emitting surface (LES) 1126, that emits light (as indicated by arrows 1106) with a first beam divergence. The linear dimensions of the LES 1126 may be less than 10 microns. The first beam divergence may be characterized by the Lambertian-like angular distribution 1108, e.g., I ∝cos θ, where I is the beam's intensity and θ is the angle measured from a vector normal to LES 1126. In the plot of the Lambertian-like angular distribution 1108, the y-axis represents the beam intensity (I) and the x-axis represents the angle of the angular distribution (0). Because a significant amount of the light's 1106 intensity and/or power falls outside of a narrow angular range (e.g., |θ|<)20°, angular distribution 1108 may be too diffuse and/or dispersed to directly employ LED 1102 as a light source 1102 in many applications.

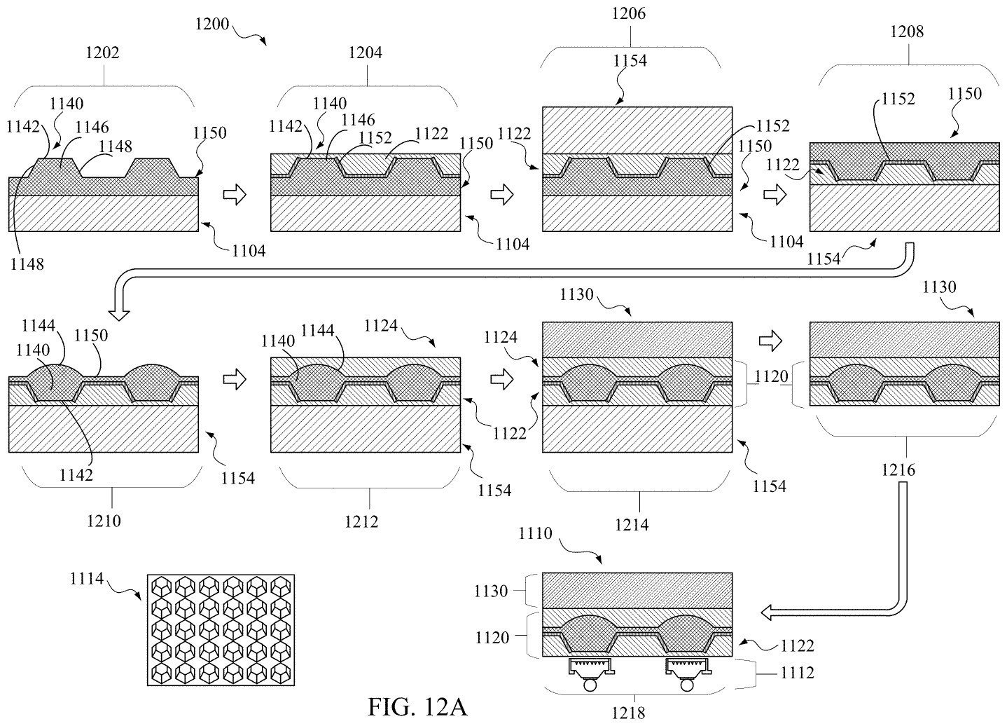

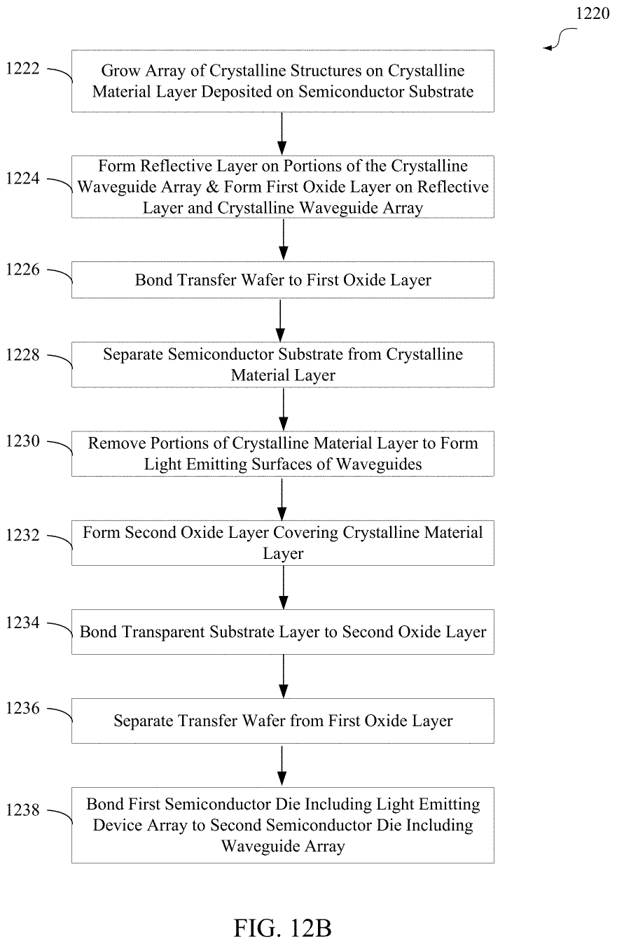

FIG. 11B illustrates a cross-sectional view of a light source 1110 that includes an array of waveguides 1114 as beam-collimating secondary optical components for an array of light emitting devices 1112, according to some embodiments. In contrast to just the light emitting device 1102 illustrated in FIG. 11A, which does not employ any secondary optical components, the light source 1100 of FIG. 11B may be employed in various applications that require a relatively collimated beam with a decreased beam divergence. The array of waveguides 1114 may include a first waveguide 1140. The array of light emitting devices may include a first light emitting device (e.g., light emitting device 1102 of FIG. 11A). As shown by the Lambertian angular distribution 1108 of FIG. 11A, a light emitting surface (LES) 1126 of light emitting device 1102 may emit a light beam with a first beam divergence. Each of the other light emitting devices of the array of light emitting devices 1112 may be another instance of the light emitting device 1102. Thus, each light emitting device of the array 1112 may emit a relatively uncollimated beam with the Lambertian-like angular distribution 1008 (e.g., a first beam divergence). For a projection view of an exemplary (but non-limiting) embodiment of the three-dimensional (3D) structure of waveguide array 1114, see the bottom of FIG. 12A. In FIG. 12A, waveguide array 1114 is a two-dimensional (2D) array of waveguides. In other embodiments, waveguide array 1114 may be a one-dimensional (1D) array of waveguides.

The array of light emitting devices 1112 may be similar to at least one of LED array 801 of FIG. 8A, LED array 970 of FIGS. 9B-9D, and/or LED array 1000 of FIG. 10. Thus, although not shown in FIG. 11B, LED array 1114 may be included in a semiconductor wafer (or a portion of a semiconductor wafer, e.g., a semiconductor die), such as but not limited to first wafer 802 of FIG. 8B or wafer 950 of FIGS. 9B-9D. In some embodiments, LED array 1114 may be included or embedded within a first semiconductor die (e.g., a portion of a wafer that has been removed or separated from other portions of the wafer), which is not shown in FIG. 11B.

Similarly, the array of waveguides 1114 may be included in a second semiconductor die 1120. Second semiconductor die 1120 may be bonded to the first semiconductor die that includes the LED array 1112. The first semiconductor die (not shown in FIG. 11B) and the second semiconductor die 1120 may be aligned such that there is a one-to-one correspondence between each LED in the LED array 1112 and each waveguide of the waveguide array 1114. For instance, first LED 1102 of LED array 1112 uniquely corresponds to first waveguide 1140 of waveguide array 1114.

Each of the waveguides, including the first waveguide 1140, of the waveguide array 1114 may be comprised of a semiconductor material. In some embodiments, the semiconductor material may include a crystalline structure, i.e., the semiconductor material may be a crystalline material. In some non-limiting embodiments, the semiconductor material of the waveguides may be gallium nitride (GaN). The semiconductor material of the waveguides may be an optically transparent material (e.g., optically transparent for at least a significant portion of the frequencies of light generated by the LEDs of the LED array 1112). The optically-transparent crystalline semiconductor material is illustrated in FIG. 11B by the cross-hatched patterning shown in first wave guide 1140, as well as each of the other waveguides of the waveguide array 1114.

First waveguide 1140 may include a first waveguide surface 1142, a second waveguide surface 1144, and a waveguide body 1146. As indicated by the cross-hatched patterning shown in the waveguides of the waveguide array 1114 (including but not limited to first waveguide 1140), the spatial volume defined by the waveguide body 1146 may be filled by the crystalline semiconductor material. As discussed more in conjunction with at least FIG. 12, the waveguides may be fabricated via one or more semiconductor processes. The semiconductor process may enable fine surface finishes on the waveguides. For example, a spatial dimension of any imperfections of the first waveguide surface 1142 and/or second waveguide surface 1144 may be less than 5 nanometers (nm).

The first semiconductor die (not shown in FIG. 11B) and the second semiconductor die 1120 may be aligned such that the first LED 1102 corresponds to the first waveguide 1140. Accordingly, the first waveguide surface 1142 may be configured and/or arranged to receive, from the LES 1126 of the first LED 1102, at least a portion of the light generated within the first LED 1102. The received light may have a first beam divergence (e.g., characterized by angular distribution 1108) of the light 1106 emitted by a Lambertian-like light source 1102, according to certain embodiments. Upon the light beam entering the first waveguide 1140, the waveguide body 1146 may transmit the light beam to the second waveguide surface 1144. The second waveguide surface 1144 may be configured to emit the light (e.g., light transmitted from the first waveguide surface 1142 to the second waveguide surface 1144, via the waveguide body 1146) out of the waveguide body 1146 and into the first waveguide's ambient environment. That is, the second waveguide surface 1144 may be configured as a light exiting surface and/or light emitting surface for the waveguide. The light exiting the second waveguide surface 1144 may have a second beam divergence that is significantly less than the first beam divergence of the beam entering the first waveguide surface 1142 (e.g., the second beam divergence is less than the first beam divergence).

The shape of the waveguide body 1146, as well as the shape of the first and/or second waveguide surfaces 1142/1144 may act to significantly collimate the beam and/or to significantly decrease the beam's divergence as it is transmitted through the first waveguide 1140. Furthermore, due to the first waveguide's 1140 optical transmission efficiency (e.g., the optical transparency of the crystalline semiconductor material) and its significant optical internal reflection characteristics, the beam experiences insignificant optical power loss as the beam's angular divergence is decreased via its traversal through the waveguide.

As shown in FIG. 11B, the shape of the waveguide body 1146 may be a tapered shape, where the surface area of the end that includes the first waveguide surface 1142 may be smaller than the surface area of the end that includes the second waveguide surface 1144. The tapered shape may be characterized by a tapering angle (e.g., the angle formed by the intersection of the first waveguide surface 1142 and the sidewalls of the waveguide body 1146). The tapering angle may be characteristic of a crystalline growth process for waveguides on a semiconductor substrate. The tapered shape of the waveguide body 1146 may act to increase the internal reflection of the first waveguide 1140 (e.g., decrease a transmission loss associated with the waveguide body 1146), as well as to enhance the decrease in the beam's divergence from the first beam divergence to the second beam divergence.

To further increase the internal reflection associated with the waveguides, as well as to further enhance the decrease in the beam's divergence from the first beam divergence to the second beam divergence, an optically reflective layer 1152 may be included in the second semiconductor die1120. The reflective layer 1152 may encapsulate at least a portion of the waveguide body 1146 (e.g., the sidewalls of the waveguide body 1146). The reflective layer 1152 may be a metallization layer (e.g., an aluminum and/or a gold layer) that prevents light leakage from the sidewalls of the waveguide body 1146.

The shape of the second waveguide surface 1144 may be formed to further decrease the beam divergence of the light emitted by the first waveguide 1140. As shown in FIG. 11B, the shape of the second waveguide surface may be similar to a spherical and/or convex lens. That is, the shape of the second waveguide surface may be a curved shape. Such a curved shape may further collimate and/or focus the light beam.

FIG. 11C illustrates an example angular distribution 1160 of light emitted by a Lambertian-like light emitting device 1102 employing a waveguide 1140 as a secondary optical component, according to certain embodiments. As discussed above, the light emitted by waveguide 1140 may have a second beam divergence that is significantly less than the first beam divergence of the light emitted by LED 1102. The second beam divergence may be characterized by the angular distribution 1160 of FIG. 11C, where I is the beam's intensity and θ is the angle measured from a vector normal to LES 1126 of first LED 1102. In the plot of the angular distribution 1108 of the light emitted by first waveguide 1140, the y-axis represents the beam intensity (I) and the x-axis represents the angle of the angular distribution (θ). A comparison of the angular distribution 1160 with angular distribution 1108 of FIG. 11A, clearly indicates that the second beam divergence is significantly less than the first beam divergence. The second beam divergence may be such that approximately 80% of the beam's power or intensity is confined to an emittance cone of approximately 20°. Thus, when employed as a secondary optical component for first LED 1102, first waveguide 1140 may act as a beam-collimating waveguide that significantly reduces the beam divergence of the light beam emitted by first LED 1102. Each of the waveguides of the waveguide array 1114 may be similar to first waveguide 1140. Accordingly, each of the waveguides of the waveguide array 1114 may act as a beam-collimating waveguide that significantly reduces the beam divergence of the light beam for its corresponding LED of the LED array 1112.

Returning to FIG. 11B, the longitudinal dimension or direction of a waveguide (e.g., first waveguide 1140) may refer to the direction of the beam's propagation or transmission within the waveguide. Therefore, the longitudinal direction of first waveguide 1140 may be substantially aligned with the direction of a vector that is orthogonal to the first waveguide surface 1142 (e.g., the vertical direction of FIG. 11B). The length of the first waveguide 1140 (or waveguide body 1146) may refer to the spatial distance between the first waveguide surface 1142 and the second waveguide surface 1144. A lateral direction and/or dimension of a waveguide may refer to a direction and/or dimension that is substantially orthogonal to the longitudinal direction and/or dimension. In some embodiments, the spatial distance corresponding to a first waveguide' s length may be measured from the first waveguide surface 1142 (which is a planar surface in the embodiment illustrated in FIG. 11B) to an “apex” of the curvature of the second waveguide surface 1144, e.g., the point on the curvature of the second waveguide surface 1144 that is furthest from the plane of the first waveguide surface 1142. The transverse (or lateral) dimension or direction of a waveguide (e.g., first waveguide 1140) may refer to a direction that is orthogonal to the longitudinal dimension of the waveguide. Therefore, the transverse (or lateral) dimension of first waveguide 1140 may be aligned with a vector that lies substantially within the “plane” of first waveguide surface 1142 (e.g., the horizontal direction of FIG. 11B). The width of the first waveguide 1140 (or waveguide body 1146) may refer to the spatial distance between opposing points on the sidewalls of the waveguide body 1146. Due to the tapered shape of waveguide body 1146, the width varies along the longitudinal dimension. Therefore, the width of first waveguide 1140 may refer to the “average” width of waveguide body 1146 (e.g., as determined via an integration along the longitudinal direction of the waveguide body 1146). An aspect ratio of waveguide may refer to the ratio waveguide's length to the waveguide's width (or average width).

The second semiconductor die 1120 may include a first dielectric layer 1122 and a second dielectric layer 1124, encapsulating the waveguide array 1114. At least one of the dielectric layers 1122/1124 may be comprised of an oxide material, such as but not limited to silicon dioxide (SiO₂). Thus, at least one of the dielectric layers may be an oxide layer (e.g., a silicon dioxide layer). In other embodiments, at least one of the dielectric layers 1122/1124 may be comprised of a nitride material, such as but not limited to silicon nitride. Thus, at least one of the dielectric layers may be a nitride layer (e.g., a silicon nitride layer). The first dielectric layer 1122 may encapsulate at least a portion of the waveguide body 1146. The first dielectric layer 1122 may cover at least a portion of the first waveguide surface 1142. The second dielectric layer 1124 may cover at least a portion of the second waveguide surface 1144. The second semiconductor die 1120 may additionally include a layer of the crystalline material 1150 that is interposed between the first semiconductor die and the second semiconductor die 1120. The first and/or second dielectric layers 1122/1124 may serve as passivation layers for the semiconductor layer 1150 and each of the waveguides (e.g., first waveguide 1140).

As further discussed in conjunction with at least FIG. 12, the waveguide array 1114 may be grown and/or formed on a continuous crystalline material layer 1150. The waveguide body of each waveguide may vertically protrude from and/or beyond the continuous crystalline material layer 1150. A proximal (or proximate) surface, with respect to the corresponding LED (e.g., the first waveguide surface 1142 of first waveguide 1140) of each waveguide of the array of waveguides may include a portion of the continuous layer of transparent crystalline material 1150. A distal surface, with respect to the corresponding LED (e.g., the second waveguide surface 1144 of first waveguide 1140) of each waveguide of the array of waveguide may be vertically displaced from the continuous layer of the transparent crystalline material 1150. The curved shape of the second waveguide surface 1144 may be formed via an etching process on the crystalline material layer 1150. As used herein, the terms distal and proximal may refer to substantially opposite directions or portions of a waveguide. A proximal (or proximate) portion of a waveguide may refer to the portion of the waveguide that is nearer the LED that will illuminate the waveguide, e.g., the portion of waveguide 1140 that includes the first waveguide surface 1142. The distal portion or end of waveguide 1140 is the portion that includes second waveguide surface 1144.

The light source 1110 may optionally include a transparent substrate layer 1130. The transparent substrate layer 1130 may be a transparent glass layer that is bonded to the second semiconductor die 1120, such that the second semiconductor die 1120 is interposed between the first semiconductor die and the transparent substrate layer 1130. In some embodiments, the transparent substrate layer 1130 may be bonded to the second dielectric layer 1124, to cover the exiting surfaces of the waveguides (e.g., second waveguide surface 1144). The second dielectric layer 1124 (and/or the first dielectric layer 1122) may be comprised of SiO2. Thus, the second dielectric layer 1124 may serve as a passivation layer for light emitting surfaces of the waveguides (e.g., second waveguide surface 1144) and/or the layer of semiconductor material 1150. The light emitted by the second waveguide surface 1144 (as well as the light emitting surface of any of the other waveguides) may be transmitted through the passivating second dielectric layer 1124 and/or the transparent substrate layer 1130 without significant power attenuation/absorption and/or dispersion.

Due to the decreased beam divergence (e.g., characterized by angular distribution 1160 of FIG. 11C), the light source 1110 (or any of the other light sources discussed herein) may be employed and/or included as a light source in a wearable device. For example, light source 1100 may be included in a wearable device that generates a virtual reality environment (e.g., head mounted display device 200 of FIG. 2) for a user wearing the wearable device. As another example, light source 1100 may be included in a wearable device that generates an augmented reality environment (e.g., near-eye display 300 of FIG. 3) for a user wearing the wearable device.

FIG. 12A illustrates a semiconductor process 1200 for fabricating the array of waveguides 1114 of FIG. 11B, according to certain embodiments. Portions of the discussion regarding semiconductor process 1200 will reference light source 1100 of FIG. 11B. Semiconductor process 1200 may begin at step 1202, where a layer of crystalline material 1150 is formed on a semiconductor substrate 1104. In some embodiments, the semiconductor substrate 1104 may be a crystal growth substrate wafer comprised of a growth material, such as but not limited to Si/A103. The crystalline material of the crystalline material layer 1150 may include, but is not limited to GaN. An array of crystalline structures is grown on the crystal growth substrate 1104. The array of crystalline structures includes at least a first crystalline structure (which corresponds to first waveguide 1140, and thus first waveguide 1140 and first crystalline structure 1140 may be interchangeably referred to throughout).

Via the steps of process 1200, each of the crystalline structures of the array is formed into a waveguide of the waveguide array 1114 (or FIG. 11B). The crystalline structure array corresponds to the waveguide array 1114 and the first crystalline structure 1140 (or first waveguide 1140) of the crystalline structure array corresponds to the first waveguide 1140 of the waveguide array 1114. Thus, the terms crystalline structure and waveguide may be used interchangeably herein. Once grown, each of the crystalline structures (or waveguides) of the crystalline (or waveguide) array, including the first waveguide 1140 extends beyond the crystalline material layer 1150. Due to the process of crystal growth, the shape and structure of the crystalline structures are significantly uniform across the crystalline structure array. Accordingly, the following discussion of the first crystalline structure (or waveguide) 1140 is applicable to each of the crystalline structures (or waveguides).

The first crystalline structure 1140 extends beyond and/or protrudes from the crystalline material layer 1150. The first crystalline structure 1140 includes a waveguide body 1146, sidewalls 1148 to the body 1146, and a first surface 1142. The first surface 1142 being a distal surface with respect to the crystalline material layer 1150. Due to the crystal growth process, the sidewalls 1148 make a tapering angle with a normal vector to the surface of the crystalline material layer 1150. The tapering angle is an inward facing angle such that, near the first surface 1142, the sidewalls 1148 are closer together than they are near the surface of the crystalline material layer 1150. Thus, the orientation of the sidewalls 1148, the tapering angle, and the first surface 1142 characterize a tapered shape of the waveguide body 1146. Although not shown in the cross sectional view of the steps of process 1200 in FIG. 12A, the first crystalline structure 1140 (or first waveguide 1140) is a symmetrical three-dimensional (3D) structure. Due to its tapered shape, the 3D waveguide body 1146 may be a pyramid-like crystalline body 1146. The first surface 1142 may form a truncated pyramid-like waveguide body 1146. In some embodiments, the crystal growth process results in the tapered waveguide body 1146 having a hexagonal pyramid shape that is truncated via the first surface 1142.

The bottom of FIG. 12A illustrates a perspective view of an exemplary (but non-limiting) embodiment of the three-dimensional (3D) structure of waveguide array 1114 (which is formed from the array of crystalline structures via the steps of process 1200). As shown in the bottom of FIG. 12A, the waveguide array 1114 is a two-dimensional (2D) array of waveguides. In other embodiments, the waveguide array 1114 may be a one-dimensional (1D) array of waveguides. Note the truncated hexagonal pyramid shape of the waveguides included in the waveguide array 1114. The light receiving surfaces (e.g., the first waveguide surface 1142 of first waveguide 1140) are shown facing upward in the perspective view of waveguide array 1114, whereas the light emitting surfaces (e.g., second waveguide surface 1144 of the first waveguide 1140) are not visible from this viewpoint. Note that the vertical orientation (with respect to the plane of the page) of the waveguide array 1114 shown in FIG. 12A is inverted from that of the vertical orientation of the waveguide array shown in FIG. 11B. For example, the “lower” plane as shown in this projection view may represent either the second dielectric layer 1124 or the transparent substrate layer 1130. Note that the vertical orientation (with respect to the plane of the page) of the waveguide array 1114 shown in FIG. 12A is inverted from that of the vertical orientation of the waveguide array shown in FIG. 11B. On a similar note, the vertical orientation of the illustrations of steps 1202-1208 of process 1200 shown in FIG. 12A is inverted from the vertical orientation of waveguide array 1114 shown in FIG. 11B. The vertical illustrations for steps 1210-1218 of process 1200 shown in FIG. 12A is the same as the vertical orientation of waveguide 1114 shown in FIG. 11B.

Process 1200 may next flow to step 1204, where an optically reflective layer 1152 may be formed on the crystalline structure array. The reflective layer 1152 may be formed on the “upper” surface to the crystalline material layer 1150. As shown in step 1204, the reflective layer 1152 may cover the sidewalls 1148 of the first crystalline structure 1140, but does not cover the first surface 1142. Also as shown in step 1204, the reflective layer 1152 may cover at least portions of the upper surface of the crystalline material layer 1150, where the covered portions are between adjacent crystalline structures of the crystalline structure array. The reflective layer 1152 may encapsulate at least a portion of the waveguide body 1146. The reflective layer 1152 may be a metallization layer (e.g., an aluminum layer) that prevents light leakage from the sidewalls 1148 of the waveguide body 1146.

Also at step 1204, a first dielectric layer 1122 may be formed on the crystalline structure array, such that each of the crystalline structures (including first crystalline structure 1140) is interposed between the first dielectric layer 1122 and the crystal growth substrate 1104. The first dielectric layer 1122 may be a dioxide layer comprised of silicon dioxide (SiO₂) or another optically transparent dioxide. In other embodiments, the first dielectric layer 1122 may be a nitride layer, e.g., a silicon nitride layer. The first dielectric layer 1122 may encapsulate at least a portion of the waveguide body 1146. The first dielectric layer 1122 may cover at least a portion of the first surface 1142. As shown in step 1204, the reflective layer 1152 may be interposed between the crystalline material layer 1150 and the first dielectric layer 1122.

At step 1206, a transfer wafer 1154 may be bonded to the first dielectric layer 1122, such that each of the crystalline material layer 1150, the reflective layer 1152, and the first dielectric layer 1122 are interposed between the crystal growth substrate 1104 and the transfer wafer 1154. Process 1200 may flow to step 1208, where the crystal growth substrate 1104 may be removed from the crystalline material layer 1150. Also note that, at least for illustrative purposes, the bonded transfer waver 1154, first dielectric layer 1122, and the crystalline material layer 1150 has been rotated 180° (in the plane of the page), such that each of their vertical orientations has been flipped.

At step 1210, a semiconductor etching process may be employed to remove a portion of the crystalline material layer 1150. The etching process may be employed to form a second surface on each of the crystalline structures. Step 1210 illustrates that, in addition to first waveguide surface 1142, first waveguide structure 1140 includes a second waveguide surface 1144. The semiconductor etching process may including forming a spherical, convex, or any other lens-like shape for the second waveguide surface 1144. In step 1212, a second dielectric layer 1124 may be formed on the waveguide array 1114. The second dielectric layer 1124 may cover the second waveguide surfaces of the waveguides, including but not limited to second waveguide surface 1144 of first waveguide 1140. Thus, the waveguides may be interposed between the first dielectric layer 1122 and the second dielectric layer 1124. The structure including the waveguide array 1114 interposed between the first and second dielectric layers 1122/1124 may be a semiconductor die (or an entire wafer), such as second semiconductor die 1120.

Process 1200 may flow to step 1214, where the transparent substrate layer 1130 may be bonded to the second dielectric layer 1124, such that the second dielectric layer 1124 is interposed between the waveguide array 1114 and the second dielectric layer 1124. At step 1216, the transfer wafer 1154 may be removed from second semiconductor die 1120. At step 1218, the second semiconductor die 1120 may be bonded to a first semiconductor die that includes an array of light emitting device 1112. The first semiconductor die may be bonded to the first dielectric layer 1122 of the second semiconductor die 1120. Via bonding the second semiconductor die 1120, which includes the array of waveguides 1114, to the first semiconductor die, which includes the LED array 1112, the light source 1110 of FIG. 11B is formed.

FIG. 12B illustrates a method 1220 for manufacturing the light source 1110 of FIG. 11B, according to certain embodiments. Method 1220 may include at least portions of one or more steps of semiconductor process 1200 of FIG. 12A. Method 1220 begins, at block 1222, where an array of crystalline structures is grown on a crystalline material layer deposited on a semiconductor substrate. For example, as in step 1202 of process 1200, crystalline structures forming the waveguide array 1114 may be grown crystalline material layer 1150. The crystalline material layer may be deposited and/or formed on at least a portion of a semiconductor wafer (e.g., crystal growth substrate 1104). At block 1224, a reflective layer (e.g., metallization layer 1252) may be formed and/or deposited on portions of the crystalline structure array (e.g., waveguide array 1114), as shown in the illustration for step 1204 of process 1200. Similar to step 1204 of process 1200, a first dielectric layer (e.g., first dielectric layer 1122) may be formed and/or deposited on the reflective layer and/or portions of the waveguide arrays.

At block 1226, a transfer wafer may be bonded to the first dielectric layer (e.g., see step 1206 of process 1200). At block 1228, the semiconductor substrate (e.g., crystal growth substrate 1104) may be physically separated from the array of crystalline structures and/or crystalline material layer (see step 1208 of process 1200). At block 1230, portions of the crystalline material later is removed (e.g., via an etching process) to form a light emitting surface (e.g., second waveguide surface 1144) for each of the waveguides (e.g., see step 1210 of process 1200).

At block 1232, a second dielectric layer (e.g., second dielectric layer 1124) is formed and/or deposited on the crystalline material layer (e.g., see step 1212 of process 1200). At block 1334, a transparent substrate layer (e.g., transparent substrate layer 1130) may be bonded to the second dielectric layer (e.g., see step 1214 of process 1200). At block 1236, the transfer wafer may be physically separated from the first dielectric layer (e.g., see step 1216 of process 1200). At block 1238, a first semiconductor die, which includes a light emitting device array, is bonded to a second semiconductor die (e.g., 1120), which included the waveguide array (e.g., see step 1218 of process 1200).

In some embodiments of both process 1200 and method 1220 as well as the other processes and methods discussed herein, the first semiconductor die (or another die) that includes the LED array is formed on a first semiconductor wafer. The second semiconductor die (or another die) that includes the waveguide array may be formed on a second semiconductor die. The first semiconductor wafer (e.g., the wafer that includes the LED array) may be sawed (or diced) to form a first plurality of semiconductor die that includes the first semiconductor die. That is, the first semiconductor die may be included in a first portion of the first semiconductor wafer. The first portion of the first semiconductor wafer may be removed from (e.g., sawed off and/or diced) the first semiconductor wafer to form the first semiconductor die. Similarly, the second semiconductor wafer (e.g., the wafer that includes the waveguide array) may be sawed (or diced) to form a second plurality of semiconductor die that includes the second semiconductor die. That is, the second semiconductor die may be included in a first portion of the second semiconductor wafer. The first portion of the second semiconductor wafer may be removed from (e.g., sawed off and/or diced) the second semiconductor wafer to form the second semiconductor die.

In some embodiments, the die that includes the LED array (e.g., the first semiconductor die) may be bonded to the die that includes the waveguide array (e.g., the second semiconductor die) after the dies are formed via sawing or dicing of the corresponding wafers. That is, each of the first and second semiconductor wafers may be diced prior to step 1238. For example, the second semiconductor wafer may be diced between steps 1236 and 1238 to form the second semiconductor die. The first semiconductor wafer may be diced (to form the first die) after the LED arrays are fabricated on the first wafer. Thus, at step 1238 the first and second semiconductor die may be aligned and bonded. Such embodiments may be referred to as die-level embodiments because individual dies are bonded to one another after the dies are sawed from the respective wafers. In other embodiments, the first and second semiconductor die may be bonded prior to dicing the wafers. For instance, the first and second semiconductor die may be bounded prior to dicing the first and second semiconductor die from the first and second semiconductor wafers, and while the first and second die are still part of their respective wafers. Such embodiments may be referred throughout as wafer-level embodiments.

### High-fill Factor Crystalline Waveguides

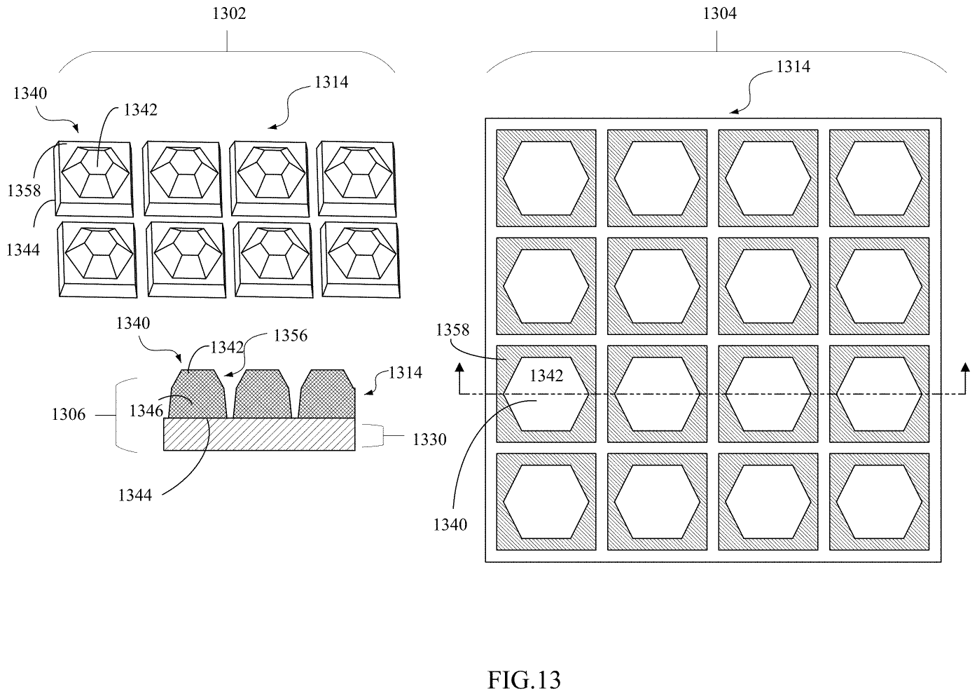

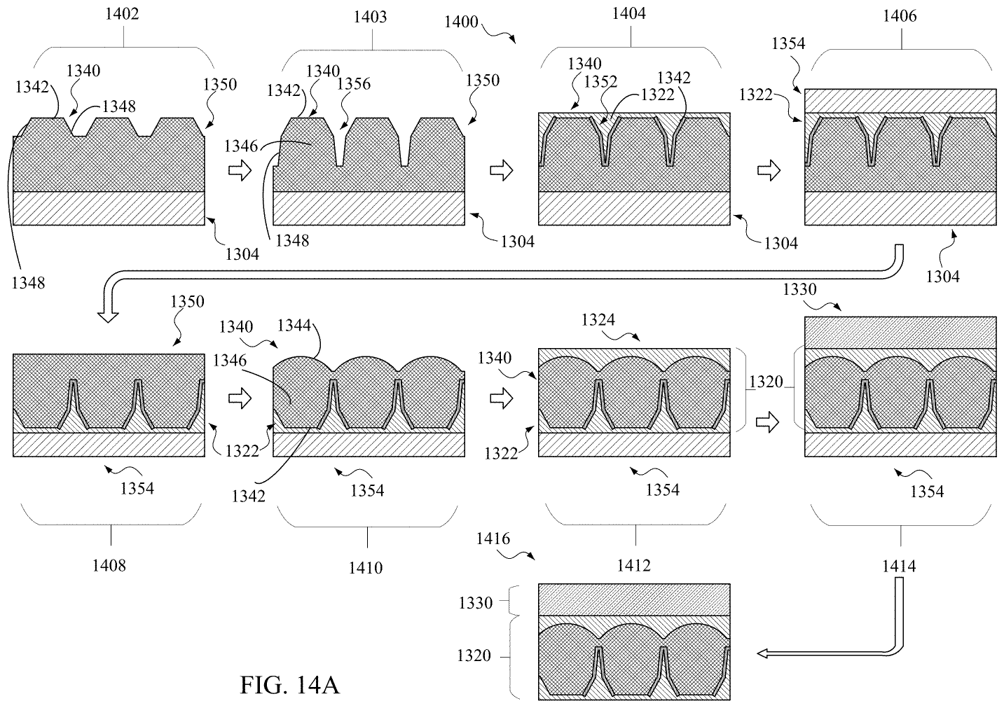

FIG. 13 illustrates an embodiment for an array of high-fill factor waveguides 1314. The waveguide embodiment shown in FIG. 13 may be referred to as a “high-fill factor” embodiment. The high-fill factor embodiments includes a waveguide array 1314. The term “fill-factor” of a waveguide array (or an embodiment) may refer to the ratio of a surface area (or linear dimension) of the light emitting surface of a waveguide (e.g., the second waveguide surface of a waveguide) to the pitch of the waveguide (e.g., the spatial or linear distance between adjacent waveguides of the array). Thus, this ratio of the high-fill factor embodiments may be larger than this ratio for the embodiments discussed in conjunction with FIGS. 11A-12B.

As user herein, the term “pitch” may refer to, or otherwise indicate, the spatial distance between adjacent elements of an array (e.g., a waveguide array or an LED array). In the various embodiments, each LED/waveguide pair of a LED array bonded to a waveguide array may serve as a light source for a pixel in a display (e.g., a pixel in a near-eye display). Thus, the pitch of the LED/waveguide arrays may match or at least be similar to the pitch of the light receiving surfaces of the pixel arrays of the display. For such embodiments, it may be advantageous for the waveguide/LED pair to fully and/or uniformly illuminate the light receiving surface of the corresponding pixel. It also may be advantageous to reduce and/or minimize any “dark spots” of illumination between adjacent light receiving surfaces of the pixels. By increasing the fill factor (e.g., the ratio of the area of the surface that emits light (e.g., the light emitting surface of the waveguide) to the pitch of the light emitting surfaces of the waveguides), the high-fill factor embodiments achieve a greater uniformity of pixel illumination and a decrease and/or an attenuation of “dark spots” of illumination between adjacent light receiving surfaces of the pixels. The various high-fill factor embodiments may increase the fill-factor ratio by increasing the surface area of the waveguide illumination surfaces.

In the high-fill factor embodiments, the light emitting surface of a waveguide (e.g., the second waveguide surface of a waveguide included in the waveguide array 1314) may have a larger surface area than the light emitting waveguide surfaces of the waveguides of embodiments discussed in conjunction with FIGS. 11A-12B, e.g., a larger fill factor. The larger surface area of the second waveguide surface of the waveguide may provide for more uniform and/or complete illumination of the pixel that the waveguide's corresponding LED serves as a light source. The waveguide may uniformly illuminate the pixel with its larger light emitting surface. Thus, “dark spots” (e.g., areas that receive little to no illumination from the waveguides) between adjacent pixels are attenuated, decreased, and/or minimized via the high-fill factor embodiments discussed herein. The high-fill factor waveguides included in waveguide array 1314 may additionally provide a greater reduction in the beam divergence for light passing through a waveguide, as compared to the waveguide array 1114 illustrated in and/or discussed in conjunction with FIGS. 11B-12B.

FIG. 13 shows three views of the high-fill factor waveguide array 1314: perspective view 1302, top view 1304, and cross sectional view 1306. The high-fill factor waveguide array 1314 may include a first high-fill factor waveguide 1340. As shown in FIG. 13, waveguide array 1314 is a 2D array of waveguides. However, similar to non-high-fill factor waveguide array 1114 of FIG. 11B, high-fill factor waveguide array 1314 may be fabricated as a 1D array of high-fill factor waveguides. A high-fill factor waveguide (e.g., first waveguide 1340) may include a light emitting structure (e.g., light emitting structure 1358) as a portion of its waveguide body. The light emitting structure may be comprised of the same material that the waveguide body is comprised of (e.g., GaN). The light emitting structure may be positioned on the portion of the tapered waveguide body that is wider than the other portion of the waveguide body. That is, the light emitting structure of a waveguide may be located at the waveguide's distal end, rather than the waveguide's proximate end. The light emitting structure may further “widen” the light emitting surface of the waveguide, which increases the surface area of the light emitting surface. Thus, the light emitting structure may increase the fill-factor of the array. The light emitting surface of a waveguide (e.g., second waveguide surface 1344) is positioned on the “underside” of the light emitting structure (e.g., light emitting structure 1358) of the perspective view 1302.

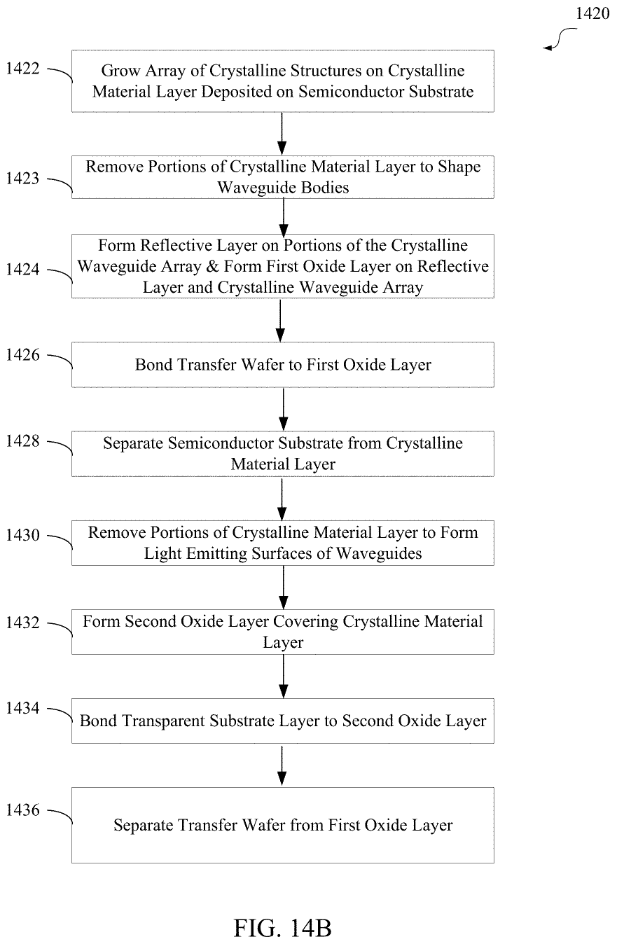

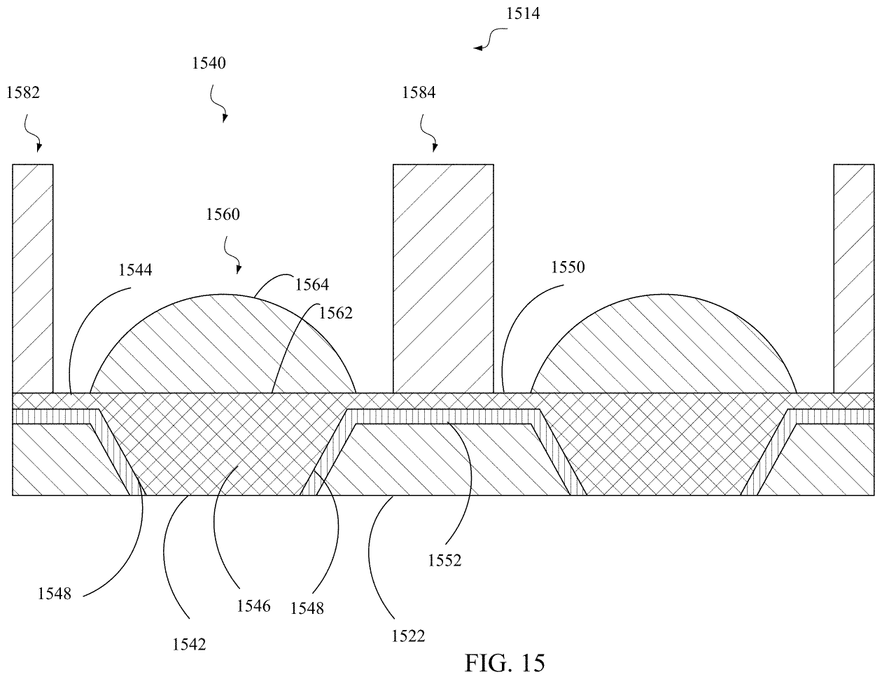

During the fabrication of high-fill factor embodiments, an etching process may be employed to alter and/or enhance the shape of the sidewalls and waveguide body of the waveguides, from the “default” shape of the sidewalls and waveguide bodies (e.g., to vary to default shape that results from the crystal growth process). This enhanced shape may include the formation of the above noted light emitting structure (e.g., light emitting structure 1358). The light emitting structure formed on the distal end of a waveguide body may be formed via this etching process. For a non-limiting example of one such variation to the default shape of a waveguide body, see the high-fill factor embodiments discussed in conjunction with FIGS. 13-14B. The enhanced shape may increase the fill factor and the beam collimation and/or divergence reduction effects of the waveguides. The enhanced shape may include varying the tapering of the waveguide body (e.g., the tapering angle), along the longitudinal dimension of the waveguide. In additional to “shaping” the waveguides via an etching process, the aspect ratio of the waveguides may be increased. The increased aspect ratio may further enhance the collimation and/or reduction in beam divergence properties of the waveguides.

Similar to first waveguide 1140 of waveguide array 1114, first waveguide 1340 of waveguide array 1314 includes a first waveguide surface 1342, a second waveguide surface 1344, and a waveguide body 1346. Note that the second waveguide surface 1344 is located on the light emitting structure 1358. The first waveguide surface 1342 receives the light generated by an LED and the second waveguide surface 1344 transmits the received light out of the waveguide body 1346. A distal end of the waveguide body 1346 (e.g., the portion of the waveguide body 1346 that is furthest from the light receiving waveguide surface (e.g., the first waveguide surface 1344)) includes the light emitting structure 1358. In the perspective view 1302, the second waveguide surface 1344 is positioned on an “underside” of the light emitting structure 1358. The light emitting structure 1358 is a block-like structure, formed of the crystalline material that comprises the waveguide body 1346, e.g., GaN. The light emitting structure 1358 may be a block-like structure. In some embodiments, the shape of the block-like structure 1358 may be a tapered shape. One or more lateral (or transverse) dimensions of the light emitting structure 1358 (e.g., a spatial dimension that is substantially orthogonal to the dimension that lies along the direction of light travel through the waveguide body 1346) may be larger than the lateral dimensions of the rest of the waveguide body 1346.

As shown in side view 1306, and similar to waveguide array 1114, waveguide array 1314 may be bonded to a transparent substrate layer 1330. Referring back to FIGS. 11B-12A, the first waveguide 1140 (and each of the other waveguides of waveguide array 1114) may have a first aspect ratio. Here, the aspect ratio may refer to a ratio of the approximate longitudinal dimension of the waveguide body to an approximate transverse or lateral dimension of the waveguide body. The first high-fill factor waveguide 1340 (and each of the other waveguides of the high-fill factor waveguide array 1314) has a second aspect ratio. A visual comparison between cross section view 1306 and the cross sectional view of light source 1110 of FIG. 11B demonstrates that the second aspect ratio (of first waveguide 1340) is larger than the first aspect ratio (of first waveguide 1140). The “height” of the light emitting structure 1358 may contribute to the increase in the aspect ratio. Note that the “width” of light emitting structure 1358 contributes to an increase in the fill-factor of waveguide 1340. The larger aspect ratio and fill factor of the high-fill factor waveguides may be achieved via etching the waveguide to vary the shape of the waveguide bodies. The larger aspect ratio and fill factor of the high-fill factor waveguides of array 1314 may provide for greater beam collimation and/or a greater decrease in beam divergence, as compared to the smaller aspect ratio of waveguide array 1114. The fabrication of such high-fill factor waveguides are discussed in conjunction with FIGS. 14A-14B. However, as shown in perspective view 1302 and cross sectional view 1306, the shape of the waveguide body 1346 approximates a hexagonal mesa. The etching process may form a trench 1356 between adjacent waveguides. The trench 1356 may decrease the average width of the waveguides, which increases the waveguide's aspect ratio.

The shape of the trench 1356 (formed via the etching process) may form a “progressive” tapered shape of the waveguide body 1346, where the progressive tapered shape enhances the beam collimation and/or the reduction in beam divergence. The etching process may vary the tapering angle along the longitudinal dimension of the waveguide body 1346. The shape of the waveguide body 1346 may be characterized by two (or more) tapering angles. Cross sectional view 1306 illustrates that the tapering angle near the second waveguide surface 1346 is less than the tapering angle closer to the first waveguide surface 1342. That is, the tapering angle near a light beam's exit from first waveguide 1340 (via the second waveguide surface 1344) may be less than the tapering angle near the light beam's entrance into the first waveguide 1340 (via the first waveguide surface 1342). The decreasing tapering angle (as the beam is transmitted through the waveguide body 1346) may result in greater beam collimation and/or an increase in the beam divergence. The greater tapering angle near the first waveguide surface 1342 (as compared to the lesser tapering angle near second waveguide surface 1342) may result is a greater distance and/or pitch between adjacent light entering waveguide surfaces (e.g., first waveguide surface 1342). In some embodiments, the tapering angle may vary continuously along the longitudinal dimension of waveguide body 1346.

These views also show that the light emitting structures (e.g., light emitting structure 1358) are formed via a discontinuous layer of the crystalline material. These discontinuities in that GaN of the light emitting structures may at least partially optically isolate the waveguides in waveguide array 1314. Such optical isolation may result is less “light leakage” between physically adjacent waveguides in waveguide array 1314. Such discontinuities may result in an array of crystalline material structures that serve as light emitting structures that increase the fill factor of the waveguide array. The light emitting structures may be formed and/or fabricated via an etching process of the crystalline material.

FIG. 14A illustrates a semiconductor process 1400 for fabricating the array of high-fill factor waveguides 1314 of FIG. 13, according to certain embodiments. Portions of the discussion regarding semiconductor process 1400 will reference high-fill factor waveguide array 1314 of FIG. 13, as well as process 1200 of FIG. 12A. Semiconductor process 1400 may begin at step 1402, where a layer of crystalline material 1350 is formed on a semiconductor substrate 1304. Similar to step 1202, an array of crystalline structures may be grown on crystalline material layer 1350 that is deposited on semiconductor substrate 1304. Thus, the semiconductor material of substrate 1304 may be a crystal growth substrate. The array of crystalline structures is formed into high-fill factor waveguide array 1314, via the etching of the crystalline material layer of steps of process 1400. The waveguide array 1314 includes a first high-fill factor waveguide 1340. The first waveguide 1340 includes a first waveguide surface 1342 and sidewalls 1348.

A comparison of the illustration of step 1402 with step 1202 demonstrates that for high-fill factor embodiments, an initial thickness of the crystalline material layer (e.g., crystalline material layer 1350) may be greater than the thickness of the corresponding crystalline material layer for the non-high-fill factor embodiments (e.g., the thickness of crystalline material layer 1150). The increased thickness of crystalline material layer 1350 may increase the fill factor of first waveguide 1340. For example, as shown in step 1403, etching away portions of crystalline material layer 1350 (with its increased thickness) enables shaping first waveguide 1340 to provide for greater reductions in the beam divergence, as a light beam travels through first waveguide 1340. In some embodiments, the increased thickness increases the aspect ratio of high-fill factor embodiments.

At step 1403, a semiconductor etching process is performed on the crystalline material layer 1350. As shown in the illustration of step 1403, the etching process may selectively remove portions of the increased thickness of the crystalline material layer to increase the fill factor of the first waveguide 1340. In some embodiments, the etching shapes the first waveguide 1340, as well as each of the other waveguides, to form hexagonal mesa-shaped waveguides bodies, with a block-like light emitting structure on the distal portions of the waveguide bodies. The etching alters the shape of the waveguide sidewalls 1348 to form a progressive tapered shape for the waveguide body 1346. The etching process may create a trench 1356 between adjacent waveguides, as well as the light emitting structure 1358. The shape of the waveguide body 1346, the light emitting structure 1358, and the trench 1356 may be varied by varying the etching process.

In some embodiments, the semiconductor substrate 1304 may be a crystal growth substrate wafer comprised of a growth material, such as but not limited to Si/AlO₃. The crystalline material of the crystalline material layer 1350 may include, but is not limited to GaN. An array of crystalline structures is grown on the crystal growth substrate 1304. The array of crystalline structures includes at least a first crystalline structure 1340.

Process 1400 may next flow to step 1404, where an optically reflective layer 1352 may be formed on the crystalline structure array. Similar to step 1204, the reflective layer 1352 at step 1404 may be formed on the “upper” surface to the crystalline material layer 1350. Also similar to step 1204, at step 1404, a first dielectric layer 1322 may be formed on the crystalline structure array, such that each of the crystalline structures (including first crystalline structure 1340) is interposed between the first dielectric layer 1322 and the crystal growth substrate 1304.

Similar to step 1206, at step 1406, a transfer wafer 1354 may be bonded to the first dielectric layer 1322, such that each of the crystalline material layer 1350, the reflective layer 1352, and the first dielectric layer 1322 are interposed between the crystal growth substrate 1304 and the transfer wafer 1354. Process 1400 may flow to step 1408. Step 1408 may be similar to step 1208 in that the crystal growth substrate 1304 may be removed from the crystalline material layer 1350. Also similar to step 1208, at step 1408, the bonded transfer waver 1354, first dielectric layer 1322, and the crystalline material layer 1350 has been rotated 180° (in the plane of the page), such that each of their vertical orientations has been flipped.

Similar to step 1210, at step 1410, a semiconductor etching process may be employed to remove a portion of the crystalline material layer 1350. The etching process may be employed to form a second surface on each of the crystalline structures. Note that the etching process performed at step 1410 is performed on a surface of the crystalline material layer 1350 that opposes the surface of the crystalline material layer 1350 that the etching process of step 1403 is performed on. Step 1410 illustrates that, in addition to first waveguide surface 1342, first waveguide structure 1340 includes a second waveguide surface 1344. The semiconductor etching process may including forming a spherical, convex, or any other lens-like shape for the second waveguide surface 1344. Similar to step 1212, at step 1412, a second dielectric layer 1324 may be formed on the waveguide array 1314. The second dielectric layer 1324 may cover the second waveguide surfaces of the waveguides, including but not limited to second waveguide surface 1344 of first waveguide 1340. Thus, the waveguides may be interposed between the first dielectric layer 1322 and the second dielectric layer 1324. The structure including the waveguide array 1314 interposed between the first and second dielectric layers 1322/1324 may be a semiconductor die (or an entire wafer), such as second semiconductor die 1320.

Process 1400 may flow to step 1414, where similarly to step 1214, the transparent substrate layer 1330 may be bonded to the second dielectric layer 1324, such that the second dielectric layer 1324 is interposed between the waveguide array 1314 and the second dielectric layer 1324. At step 1416, the transfer wafer 1354 may be removed from second semiconductor die 1320.

FIG. 14B illustrates a method 1420 for manufacturing the high-fill factor waveguide array 1314 of FIG. 13, according to certain embodiments. Method 1420 may include at least portions of one or more steps of semiconductor process 1400 of FIG. 14A. Method 1420 begins, at block 1422, where an array of crystalline structures is grown on a crystalline material layer deposited on a semiconductor substrate. For example, as in step 1402 of process 1400, crystalline structures forming the waveguide array 1314 may be grown crystalline material layer 1350. The crystalline material layer may be deposited and/or formed on at least a portion of a semiconductor wafer (e.g., crystal growth substrate 1304).

At block 1423, portions of the crystalline material layer are removed to shape waveguide bodies from the crystalline structures. The portions of the crystalline material may be removed via a semiconductor etching process, as discussed in conjunction with step 1403 of process 1400. At block 1424, a reflective layer (e.g., metallization layer 1352) may be formed and/or deposited on portions of the crystalline structure array (e.g., waveguide array 1314), as shown in the illustration for step 1404 of process 1400. Similar to step 1404 of process 1400, a first dielectric layer (e.g., first dielectric layer 1322) may be formed and/or deposited on the reflective layer and/or portions of the waveguide arrays. At block 1426, a transfer wafer may be bonded to the first dielectric layer (e.g., see step 1406 of process 1400). At block 1428, the semiconductor substrate (e.g., crystal growth substrate 1304) may be physically separated from the array of crystalline structures and/or crystalline material layer (see step 1408 of process 1400). At block 1430, portions of the crystalline material later is removed (e.g., via an etching process) to form a light emitting surface (e.g., second waveguide surface 1344) for each of the waveguides (e.g., see step 1410 of process 1400). Note that the etching process performed at step 1430 is performed on a surface of the crystalline material layer 1350 that opposes the surface of the crystalline material layer 1350 that the etching process of step 1423 is performed on.

At block 1432, a second dielectric layer (e.g., second dielectric layer 1324) is formed and/or deposited on the crystalline material layer (e.g., see step 1412 of process 1400). At block 1434, a transparent substrate layer (e.g., transparent substrate layer 1330) may be bonded to the second dielectric layer (e.g., see step 1414 of process 1400). At block 1436, the transfer wafer may be physically separated from the first dielectric layer (e.g., see step 1416 of process 1400). At block 1338, a first semiconductor die, which includes a light emitting device array, is bonded to a second semiconductor die (e.g., 1120), which included the waveguide array (e.g., see step 1218 of process 1200).

### Baffled Waveguides

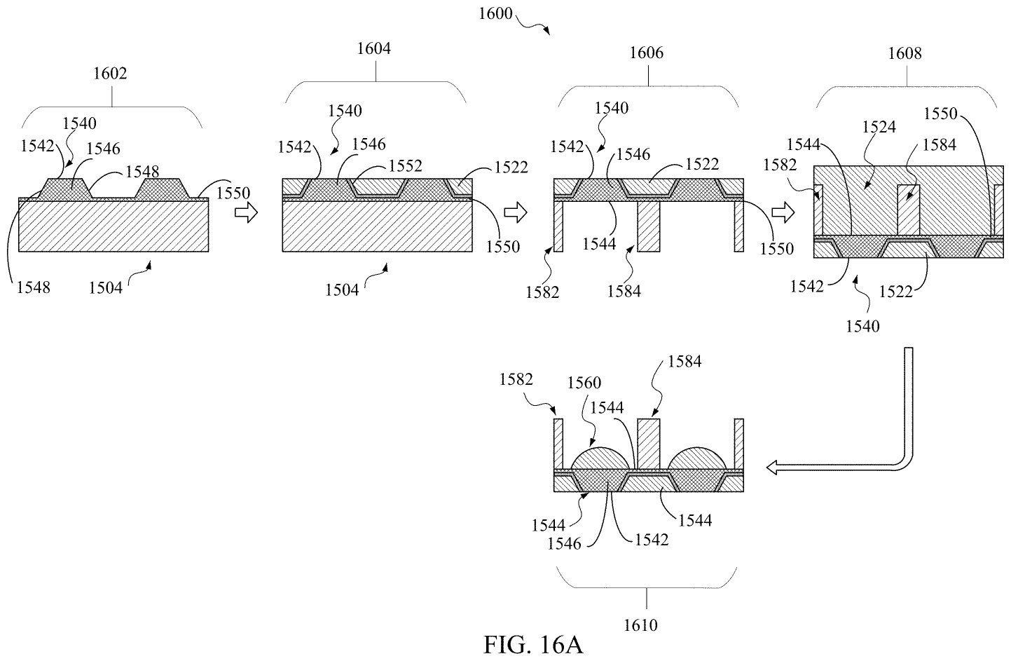

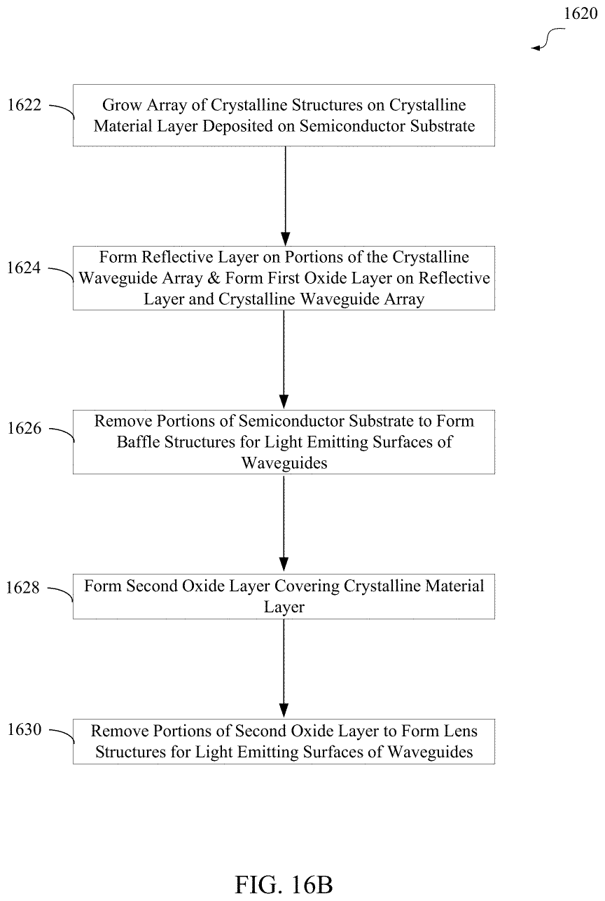

FIG. 15 illustrates an embodiment for an array of crystalline baffled waveguides 1514. The waveguide embodiment shown in FIG. 15 may be referred to as a “baffled” embodiment because non-transparent baffle structures, which optically isolate each waveguide from adjacent waveguides, provide enhanced collimation and/or reduction in the divergence of light beams passing through the waveguides. The optical isolation of the baffle structures also reduce “light leakage” between adjacent waveguides. The waveguides may additionally and/or alternatively include oxide “lens” structures, which act as secondary or tertiary optical components that provide even further collimation and/or reduction in the divergence of light beams passing through the waveguides. In various embodiments discussed throughout, either one of or both of the semiconductor baffle structures and/or the dielectric lens structures discussed in conjunction with at least FIGS. 15-16B, may be adapted and additionally deployed in any of the embodiments discussed in conjunction with FIGS. 11B-14B.

As shown in FIG. 15, crystalline waveguide 1514 includes first waveguide 1540. Similar to other waveguides discussed throughout, first waveguide 1540 includes a first waveguide surface 1542 for an LED's light to enter the waveguide body 1546 of the first waveguide 1540. The waveguide body 1546 transmits the light from the first surface 1542 to the second waveguide surface 1544 (which is a planar surface in FIG. 15). Similar to other embodiments discussed throughout, the second waveguide surface 1542 may emit the light beam (with its reduced beam divergence) out of the waveguide body 1546. As discussed further below, the emitted beam may enter the dielectric lens structure 1560 for further beam shaping (e.g., collimation and/or reduction in divergence).

The dielectric lens structure 1560 may be comprised of a transparent dioxide material, such as but not limited to SiO₂. Thus, the dielectric lens structure 1560 may be a dioxide lens structure. In other embodiments, the dielectric material employed to fabricate the dielectric lens structure 1560 may be silicon nitride. Due to a difference between the index of refraction of the semiconductor material of the waveguide body 1546 and the index of refraction of the dielectric material (e.g., silicon dioxide or silicon nitride) of the dielectric lens structure 1560, the light may be refracted and/or lensed via the lens structure 1560. As shown in FIG. 15, at least one surface of the dielectric lens structure 1560 (e.g., a second lens surface 1562 which serves as the lens' 1560 light emitting surface) may be have a shape that is similar to spherical and/or convex lens. Another surface of the dielectric lens structure 1560 (e.g., a first lens surface 1562 that serves as the lens' light entering surface) may be a planar surface to mate with the light emitting surface of first waveguide 1540 (e.g., second waveguide surface 1544). Light emitted by second waveguide surface 1544 may be received by first lens surface 1562, pass through lens structure 1560, and be emitted by second lens surface 1564. Thus, the lens structure 1560 may further shape the profile of the light beam emitted by first waveguide 1540, e.g., the lens structure 1560 may further collimate and/or reduce the divergence of an LED's light beam.

Note that the dielectric lens structure 1560 may serve as a passivation layer for the first waveguide 1540. One or more baffle structures (e.g., first baffle structure 1582 and second baffle structure 1584) may extend from and/or protrude from the semiconductor material layer 1550 (or a secondary dielectric layer, such as but not limited to second dielectric layer 1124 of FIG. 11B and/or second dielectric layer 1324 of FIG. 14A). As discussed below, the baffle structure may serve to further optically isolate and/or further shape the beam profile (e.g., increase collimation and/or reduce beam divergence). Although shown as two separate baffle structures in FIG. 15, first and second baffle structures 1582 and 1584 may be a single 3D baffle structure extending into and out of the page.

The baffle structures (the first and second baffle structures 1582/1584) may be comprised of a non-transparent semiconductor material, such as but not limited to silicon (Si). The non-transparent semiconductor material may be an optically absorbing material, at least for the frequencies emitted by the LEDs. The baffle structures of a waveguide may serve to effectively absorb portions of the light beam (emitted by the waveguide) that would “interfere” with the light beams emitted by adjacent waveguides. That is, the baffle structures further collimate the light beam emitted by a waveguide by removing portions of the light beam that are near the edges of the beam profile, which still fall outside of the desired cone of emittance for various applications that employ LEDs as light sources.

As noted above, the waveguides may additionally and/or alternatively include a dielectric lens structure (e.g., dielectric lens structure 1560) that is aligned with the light emitting surface of the waveguide (second waveguide surface 1544 of first waveguide 1540). The dielectric lens structure may be comprised of an optically transparent semiconductor material (e.g., a dielectric material) that refracts incoming light such that the beam divergence of the incoming light beam is decreased upon traveling through the lens structure. The dielectric material may be a dioxide, such as but not limited to silicon dioxide (SiO₂). Thus, the dielectric lens may be an oxide lens. The alignment of the dielectric lens structure with its corresponding waveguide is such that the lens structure receives the light beam emitted from the light emitting surface of the waveguide. As discussed throughout, the angular divergence of the light emitted by the emitting surface of the waveguide has already been significantly reduced via its passage through the waveguide body. The beam emitted by the waveguide is transmitted through (and refracted by) the dielectric lens structure for further collimation and/or divergence reduction. The dielectric lens structure may serve as a spherical and/or convex lens that acts to further collimate and/or reduce the beam's divergence. That is, the dielectric lens structure may serve as a collimating secondary optical component to the combination of an LED and semiconductor waveguide (or as a tertiary optical component for the LED).

FIG. 16A illustrates a semiconductor process 1600 for fabricating the array of baffled waveguides 1514 of FIG. 15, according to certain embodiments. Portions of the discussion regarding semiconductor process 1600 will reference baffled waveguide array 1514 of FIG. 15, as well as process 1200 of FIG. 12A and/or process 1400 of FIG. 14A. For example, process 1200 and/or process 1400 may be adapted to include the semiconductor baffle structures (first and second baffle structures 1582 and 1584) and/or dielectric lens structures (dielectric lens structure 1560) for the waveguides of the corresponding waveguide arrays.

Semiconductor process 1600 may begin at step 1602, where a layer of crystalline material 1550 is formed on a semiconductor substrate 1504. Similar to step 1202 of process 1200, an array of crystalline structures may be grown on a crystalline material layer 1550 that is deposited on semiconductor substrate 1504. Thus, the semiconductor material of substrate 1504 may be a crystal growth substrate. The semiconductor substrate 1504 may be a semiconductor wafer. The semiconductor material of substrate 1504 may be an optically non-transparent and/or optical absorptive material, such as but not limited to silicon (Si). Semiconductor substrate 1504 may be a silicon wafer. The array of crystalline structures is formed into baffled waveguide array 1514, via the steps of process 1600. The waveguide array 1514 includes a first baffled waveguide 1540. The first waveguide 1540 includes a first waveguide surface 1542, waveguide body 1546, and sidewalls 1548 encasing the waveguide body 1546.

At step 1604 (and similar to step 1204 of process 1200), an optically reflective layer 1552 may be formed on the crystalline structure array. The reflective layer 1552 formed at step 1604 may be formed on the “upper” surface to the crystalline material layer 1550. Also similar to step 1204, at step 1604, a first dielectric layer 1522 may be formed on the crystalline structure array, such that the body of each of the crystalline structures (including waveguide body 1546 of first crystalline structure 1540) is interposed between the first dielectric layer 1522 and the semiconductor substrate 1504. Note that for first waveguide 1140 of waveguide array 1114 (e.g., see FIG. 12A), a thin portion of the first dielectric layer covers the planar first waveguide surface 1142 of first waveguide 1140. In contrast, the first dielectric layer 1522 of baffled waveguide array 1514 (e.g., see FIG. 15) does not cover the planar first waveguide surface 1542 of first waveguide 1540. The embodiments may vary, and in some embodiments (e.g., first waveguide 1140, first waveguide 1340, and first waveguide body 1540), the optically transparent first dielectric layer (e.g., first dielectric layer 1122, first dielectric layer 1322, and first dielectric layer 1522) may completely cover the light-entering first waveguide surface (e.g., first waveguide surface 1142, first waveguide surface 1342, and first waveguide surface 1142). In other embodiments, the first dielectric layer may only partially cover, or not cover at all, the first waveguide surface of the waveguide.

Process 1600 flows to step 1606, where an etching process is performed on the semiconductor substrate 1504. As shown in the illustration for step 1606, the semiconductor etching process selectively removes portions of the semiconductor substrate 1504 from the semiconductor material layer 1550. The etching process exposes a light emitting surface for each of the waveguides. For example, a second waveguide surface 1544 is exposed for first waveguide 1540. The second waveguide surface 1544 will be the light emitting surface for first waveguide 1540. In this embodiment, each of the first waveguide surface 1542 and second waveguide surface 1544 of first waveguide 1540 are planar surfaces. In contrast, and as shown in FIG. 12A, for first waveguide 1140 of waveguide array 1114, only the first waveguide surface 1142 is a planar surface. The second waveguide surface 1144 (e.g., the light emitting surface) of first waveguide 1140 is a curved surface. Any of the embodiments discussed herein may include a planar light emitting surface (e.g., the second waveguide surface of the waveguide).

The portions of the non-transparent (or opaque) semiconductor substrate 1504 that are not removed via the etching process form non-transparent baffle structures that optically isolate each of the waveguides from their adjacent waveguides. As shown in step 1606, a first baffle structure 1582 and a second baffle structure 1584 optically isolate first waveguide 1540 from the other waveguides of waveguide array 1514. Because the first baffle structure 1582 and the second baffle structure 1584 are oriented along the longitudinal dimension of the first waveguide 1540, the baffle structures may act to further collimate and/or reduce the beam divergence of light emitted by the second surface 1544 of first waveguide 1540. Although not shown in the 2D plane of FIG. 16A, the baffle structures may be 3D baffle structures that completely surrounding a light beam emitted for second waveguide surface 1544 of first waveguide 1540. In some embodiments, first baffle structure 1582 and second baffle structure 1584 may form a 3D continuous baffle structure that surrounds the light beam emitted by first waveguide 1540.

Similar to step 1212, in step 1608, a second dielectric layer 1524 may be formed on the waveguide array 1514. The second dielectric layer 1524 may cover the second waveguide surfaces, e.g., the light emitting surfaces of the waveguides including but not limited to second waveguide surface 1544 of first waveguide 1540. As shown in the illustration for step 1608, the second dielectric layer 1524 may essentially encapsulate the baffle structures (e.g., first baffle structure 1582 and second baffle structure 1584).

Process 1600 may flow to step 1610. For at least purposes of clarity, the vertical (or longitudinal) orientation of waveguide array 1514 has been flipped for the illustration of step 1610. At step 1610, an etching process may be performed on the second dielectric layer 1524. The etching process may be specific to the oxide material (e.g., SiO₂) of second dielectric layer 1524. That is, the etching process of step 1608 may not significantly etch (or remove) the semiconductor material (e.g., Si) of the baffle structures (e.g., first baffle structure 1582 and second baffle structure 1584), or the semiconductor material of the semiconductor material layer 1550 and/or the waveguides (e.g., GaN). The etching process may be performed to remove portions of the second dielectric layer 1524, such that only an dielectric lens structure (e.g., dielectric lens structure 1560) remains for each of the waveguides (e.g., first baffled waveguide 1540).

FIG. 16B illustrates a method 1620 for manufacturing the baffled waveguide array 1514 of FIG. 15, according to certain embodiments. Method 1620 may include at least portions of one or more steps of semiconductor process 1600 of FIG. 16A. Method 1620 begins, at block 1622, where an array of crystalline structures is grown on a crystalline material layer deposited on a semiconductor substrate. Similar to step 1602 of process 1600 of FIG. 16A, crystalline structures forming the waveguide array 1514 may be grown crystalline material layer 1550. The crystalline material layer may be deposited and/or formed on at least a portion of a semiconductor wafer (e.g., crystal growth substrate 1504).

At block 1624, a reflective layer (e.g., metallization layer 1552) may be formed and/or deposited on portions of the crystalline structure array (e.g., waveguide array 1514). Similar to step 1204 of process 1200, a first dielectric layer (e.g., first dielectric layer 1522) may be formed and/or deposited on the reflective layer and/or portions of the waveguide arrays. As shown in step 1604 of process 1600, the reflective layer may provide at least partial optical isolation of each waveguide in the waveguide array from each of the other waveguides.

At block 1626, portions of the semiconductor substrate are removed (e.g., via a semiconductor etching process performed on the semiconductor substrate) to form one or more baffle structures for the light emitting surface of each waveguide of the waveguide array. For example, as shown in the illustration for step 1606 of process 1600, first and second baffle structures 1582/1584 may be formed, via the etching of semiconductor substrate 1504, to baffle (or constrain) via absorptive processes the light emitted by the second waveguide surface 1544 of first waveguide 1540. At block 1628, and as shown in the illustration for step 1608 of process 1600, a second dielectric layer may be formed to cover the crystalline material layer (e.g., crystalline material layer 1550) and/or the light emitting surfaces of the waveguides (e.g., second waveguide surface 1544 of first waveguide 1540). At block 1630, and as shown in the illustration for step 1610 of process 1600, portions of the second dielectric layer are removed (e.g., via an etching process performed on the second dielectric layer) to form one or more dielectric lens structures for the light emitting surface of each waveguide of the waveguide array. For example, as shown in the illustration for step 1610 of process 1600, dielectric lens structure 1560 may be formed, via the etching of second dielectric layer 1524, to shape the beam emitted via the planar second waveguide surface 1544 of first waveguide 1540.

### Embossing Tools for Fabricating Waveguide Arrays

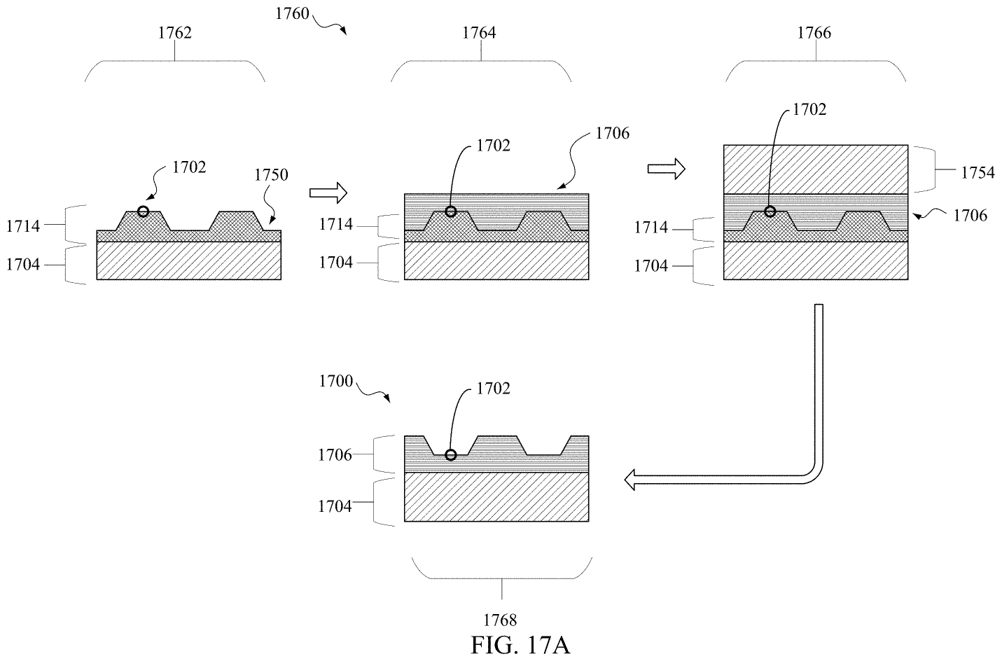

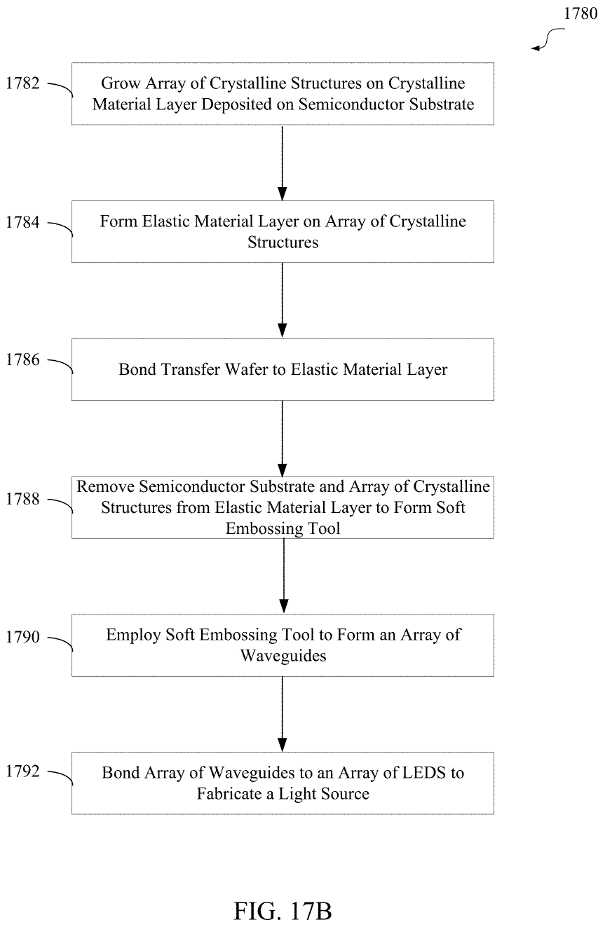

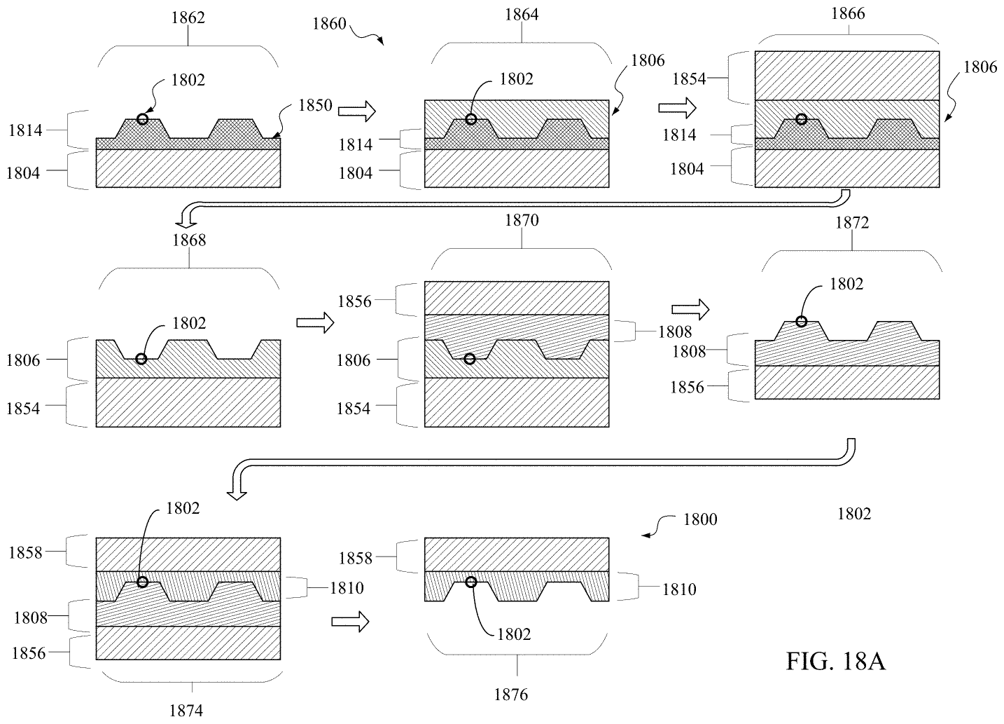

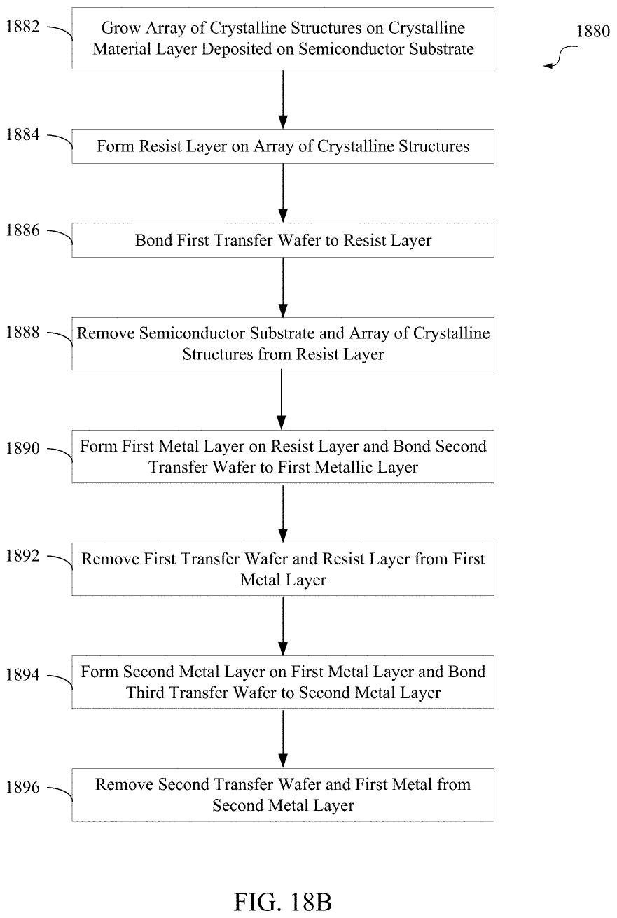

Various embodiments may include fabricating either a “soft” or a “hard” imprinting and/or embossing tool. Such an embossing tool may be employed to fabricate waveguides in materials other than the crystalline material used to grow the crystalline structures comprising the waveguide bodies (e.g., GaN) via an imprint and/or embossing process (e.g., a nanoimprint lithography process). For instance, these tools may be employed to imprint and/or emboss waveguides similar to the ones discussed herein in a non-crystalline material (e.g., silica or another refracting material). Processes 1760 and 1780 of FIGS. 17A-17B are directed towards the fabrication of a “soft” imprinting and/or embossing tool. Processes 1860 and 1880 of FIGS. 18A-18B are directed towards the fabrication of a “hard” imprinting and/or embossing tool.

FIG. 17A illustrates a semiconductor process 1760 for fabricating a soft embossing tool 1700 for embossing a waveguide array in a non-crystalline material, according to certain embodiments. Portions of the discussion regarding semiconductor process 1760 will reference waveguide array 1114 of FIG. 11B, as well as process 1200 of FIG. 12A. Semiconductor process 1760 may begin at step 1762, where a layer of crystalline material 1750 is formed on a semiconductor substrate 1704. Similar to step 1202 of process 1200, an array of crystalline structures 1714 may be grown on crystalline material layer 1750 that is deposited on semiconductor substrate 1704. Thus, the semiconductor material of substrate 1704 may be a crystal growth substrate. Due to the crystalline growth process, the shape of the array of crystalline structures 1714 is similar to the waveguide array 1114. Thus, based on the crystal growth process, the shape of the crystalline structures is significantly uniform across the array of crystalline structures 1714. Process 1760 includes “transferring” the shape of the crystalline structure array 1714 (and thus the shape waveguide array 1114 of FIG. 11B) to the soft embossing tool 1700. Thus, a reference point 1702 is shown in the illustrations for the steps of process 1760 to track the transfer of the shape of the crystalline structure array 1704 to the soft embossing tool 1700.

At step 1764, a layer of an elastic (or “soft”) material 1706 may be formed (or deposited) on crystalline structure array 1714. In some non-limiting embodiments, the elastic material layer 1706 may be a polymer layer, such as but not limited to a layer of a silicone (or silicone-like) material. In some embodiments, the elastic material layer 1706 may be comprised of polydimethylsiloxane (PDMS). Note reference point 1702 in the illustration of step 1764. Because the layer of elastic material 1706 “mates” with the array of crystalline structures 1714, the shape of the layer of elastic material 1706 is a complement to the shape of the array of crystalline structures 1714. At step 1766, a transfer wafer 1754 may be bonded to the elastic material layer 1706.

At step 1768, the semiconductor substrate 1704 and the array of crystalline structures 1714 may be removed (or physically separated from) the elastic material layer 1706, to form the soft embossing tool 1700. The embossing tool 1700 may include the elastic material layer 1706 that has a shape that is a complement to the shape of the waveguide array 1114 of FIG. 11B. In some embodiments, the embossing tool may also include the transfer wafer 1704. In other embodiments, the elastic material layer 1706 may be transferred to another rigid body (e.g., another wafer). For purposes of clarity, the vertical orientation of the elastic material layer 1706 and the transfer wafer 1704 has been flipped in the illustration of step 1768. Because the embossing tool 1700 (e.g., the elastic material layer 1706) has a shape that is the complement to the array of waveguides 1114 of FIG. 11B, embossing a waveguide material (e.g., material with waveguide properties and/or a material that refracts lights) with embossing tool 1700 will result in waveguides that are shaped to that of waveguide array 1114.

FIG. 17B illustrates a method 1780 for manufacturing the soft imprinting tool 1700 of FIG. 17A, according to certain embodiments. Method 1780 may include at least portions of one or more steps of semiconductor process 1760 of FIG. 17A. Method 1780 begins, at block 1782, where an array of crystalline structures is grown on a crystalline material layer deposited on a semiconductor substrate. For example, as in step 1762 of process 1760, crystalline structures forming the crystalline structure array 1714 may be grown crystalline material layer 1750. The crystalline material layer may be deposited and/or formed on at least a portion of a semiconductor wafer (e.g., crystal growth substrate 1704).

At block 1784, and similar to step 1764 of process 1760, an elastic material layer (e.g., elastic material layer 1706) may be formed (or deposited on) the array of crystalline structures. At block 1786, and similar to step 1766 of process 1760, a transfer wafer (e.g., transfer wafer 1754) may be bonded to the elastic material layer. At block 1788, and similar to step 1768, a soft embossing tool (e.g., soft embossing tool 1700) may be formed by removing the semiconductor substrate and the array of crystalline structures from the layer of elastic material. At block 1790, the soft embossing tool may be employed to form an array of waveguides (e.g., via a nanoimprint lithography process). At block 1792, the array of waveguides may be employed to fabricate a light source.

FIG. 18A illustrates a semiconductor process 1860 for fabricating a hard embossing tool 1800 for embossing a waveguide array in a non-crystalline material, according to certain embodiments. Portions of the discussion regarding semiconductor process 1860 will reference waveguide array 1114 of FIG. 11B, as well as process 1200 of FIG. 12A. Semiconductor process 1860 may begin at step 1862, where a layer of crystalline material 1850 is formed on a semiconductor substrate 1804. Similar to step 1202 of process 1200, an array of crystalline structures 1814 may be grown on crystalline material layer 1850 that is deposited on semiconductor substrate 1804. Thus, the semiconductor material of substrate 1804 may be a crystal growth substrate. Due to the crystalline growth process, the shape of the array of crystalline structures 1814 is similar to the waveguide array 1114. Thus, based on the crystal growth process, the shape of the crystalline structures is significantly uniform across the array of crystalline structures 1814. Process 1860 includes “transferring” the shape of the crystalline structure array 1814 (and thus the shape waveguide array 1114) to the hard embossing tool 1800. Thus, a reference point 1802 is shown in the illustrations for the steps of process 1860 to track the transfer of the shape of the crystalline structure array 1804 to the soft embossing tool 1800.

At step 1864, a layer of a photoresist material 1806 may be formed (or deposited) on crystalline structure array 1814. Note reference point 1802 in the illustration of step 1864. Because the layer of photoresist 1806 “mates” with the array of crystalline structures 1814, the shape of the layer of photoresist 1806 is a complement to the shape of the array of crystalline structures 1814. Rather than a soft and/or elastic material (e.g., PDMS as employed at step 1764 of process 1760 of FIG. 17A), a photoresist material may be employed at step 1864, such that one or more “hard” layers (e.g., layers of metal) may be formed when fabricating hard embossing tool 1800 (e.g., see steps 1870 and 1874 of process 1860). At step 1866, a first transfer wafer 1854 may be bonded to the photoresist layer 1806.

At step 1868, the semiconductor substrate 1804 and the array of crystalline structures 1814 may be removed (or physically separated from) the photoresist layer 1806. Note that the vertical orientation of the first transfer wafer 1854 and the photoresist layer 1806 has been flipped in the illustration for step 1868. At step 1870, a first layer of “hard” material 1808 may be formed of the photoresist layer 1806. The hard material of the first hard material layer 1808 may be a first metal, such as but not limited to copper (Cu). Thus, first hard layer 1808 may be a first metal layer. Because the first metal layer 1808 mates with the photoresist layer 1806, the shape of the first hard metal layer 1808 may be a complement to the shape of the photoresist layer 1806. That is, the shape of the first metal layer 1808 is a complement to the complement of the shape of the array of crystalline structures 1814, i.e., the shape of the array of crystalline structures 1814, which is the shape of the array of waveguides to be fabricated via hard embossing tool 1800. To emboss an array of waveguides, the shape of the embossing tool may be required to be similar to the shape of the array of waveguides to be embossed. Thus, the embossing tool 1800 may require the shape of the photoresist layer 1806. Accordingly, the shape of the first metal layer 1808 may be transferred to a second metal layer (e.g., see second metal layer 1810 of step 1874). Also at step 1870, a second transfer wafer 1856 may be bonded to the first metal layer 1808.

At step 1872, the first transfer wafer 1854 and the photoresist layer 1806 may be removed from the first metal layer 1808. Note that, in the illustration of step 1872, the vertical orientation of the second transfer wafer 1856 and the first metal layer 1808 have been flipped. At step 1874, the shape of the first metal layer may be transferred to a second metal layer. For example, a second metal layer 1810 may be formed of the first metal layer 1808. In non-limiting embodiments, the second metal layer may be comprised of a second metal, such as but not limited to nickel. Because the second metal layer 1810 mates with the first metal layer 1808, the shape of the second metal layer 1810 is the complement to the shape of the first metal layer 1808 (e.g., a shape that is the complement to the shape of the waveguide array to be embossed). Also at step 1874, a third transfer wafer 1858 may be bonded to the second metal layer 1810.

At step 1876, the hard embossing tool 1800 may be formed by removing the second transfer wafer 1856 and the first metal layer 1808 from the second metal (or hard) layer 1810. Again, for clarity, the vertical orientation of the third transfer wafer 1858 and the second metal layer 1810 has been flipped. Thus, the hard transfer tool may include the second metal layer 1810 and the third transfer wafer 1858 (or another rigid body). The hard embossing tool may be employed to emboss or imprint waveguide arrays in a manner similar to that of soft embossing tool 1700.

FIG. 18B illustrates a method 1880 for manufacturing the hard imprinting tool 1800 of FIG. 18A, according to certain embodiments. Method 1880 may include at least portions of one or more steps of semiconductor process 1860 of FIG. 18A. Method 1880 begins, at block 1882, where an array of crystalline structures is grown on a crystalline material layer deposited on a semiconductor substrate. For example, as in step 1862 of process 1860, crystalline structures forming the crystalline structure array 1814 may be grown crystalline material layer 1850. The crystalline material layer may be deposited and/or formed on at least a portion of a semiconductor wafer (e.g., crystal growth substrate 1804).

At block 1884, and similar to step 1864 of process 1860, a photoresist layer (e.g., elastic material layer 1806) may be formed (or deposited on) the array of crystalline structures. Thus, at block 1884, the complement of the shape of the crystalline structure array may be transferred to the photoresist layer. At block 1886, and similar to step 1866, a first transfer wafer (e.g., first transfer wafer 1854) may be bonded to the photoresist layer. At block 1888, and similar to step 1868, the semiconductor substrate and the array of crystalline structures may be removed from the resist layer. At block 1890, and similar to step 1870, a first metal layer (e.g., first metal layer 1808) may be formed and/or deposited on the photoresist layer. Thus, at block 1890, the complement of the shape of the layer of photoresist layer may be transferred to the first metal layer. Also at block 1890, a second transfer wafer (e.g., second transfer wafer 1856) may be bonded to the first metal layer. At block 1892, and similar to step 1872, the first transfer wafer and the photoresist layer may be removed from the first metal layer.

At step 1894, and similar to step 1874, a second metal layer (e.g., second metal layer 1810) may be formed on the first metal layer. Thus, at block 1894, the complement of the shape of the first metal layer may be transferred to the second metal layer. Also at block 1894, a third transfer wafer (e.g., third transfer wafer 1858) may be bonded to the second metal layer. At block 1896, a hard embossing tool (e.g., hard embossing tool 1800) may be formed by removing the second transfer wafer and the first metal layer from the second metal layer.

### Artificial Reality Systems

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

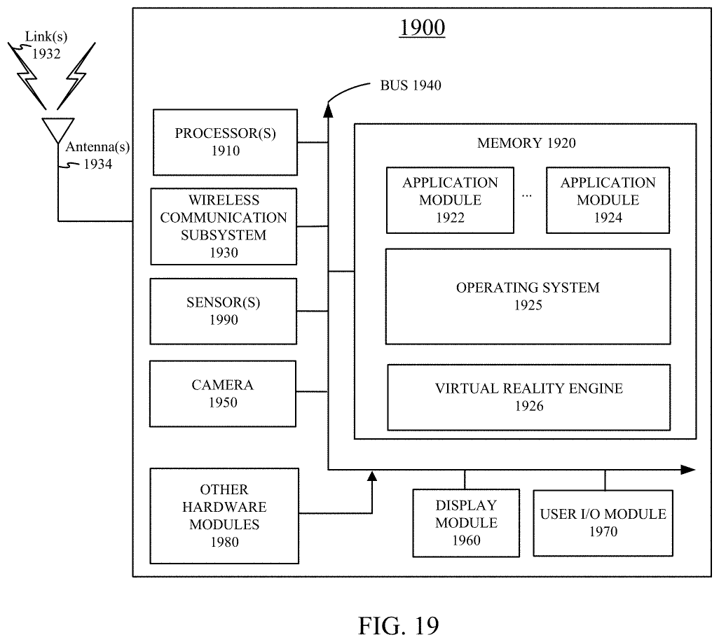

FIG. 19 is a simplified block diagram of an example electronic system 1900 of an example near-eye display (e.g., HMD device) for implementing some of the examples disclosed herein. Electronic system 1900 may be used as the electronic system of an HMD device or other near-eye displays described above. In this example, electronic system 1900 may include one or more processor(s) 1910 and a memory 1920. Processor(s) 1910 may be configured to execute instructions for performing operations at a number of components, and can be, for example, a general-purpose processor or microprocessor suitable for implementation within a portable electronic device. Processor(s) 1910 may be communicatively coupled with a plurality of components within electronic system 1900. To realize this communicative coupling, processor(s) 1910 may communicate with the other illustrated components across a bus 1940. Bus 1940 may be any subsystem adapted to transfer data within electronic system 1900. Bus 1940 may include a plurality of computer buses and additional circuitry to transfer data.

Memory 1920 may be coupled to processor(s) 1910. In some embodiments, memory 1920 may offer both short-term and long-term storage and may be divided into several units. Memory 1920 may be volatile, such as static random access memory (SRAM) and/or dynamic random access memory (DRAM) and/or non-volatile, such as read-only memory (ROM), flash memory, and the like. Furthermore, memory 1920 may include removable storage devices, such as secure digital (SD) cards. Memory 1920 may provide storage of computer-readable instructions, data structures, program modules, and other data for electronic system 1900. In some embodiments, memory 1920 may be distributed into different hardware modules. A set of instructions and/or code might be stored on memory 1920. The instructions might take the form of executable code that may be executable by electronic system 1900, and/or might take the form of source and/or installable code, which, upon compilation and/or installation on electronic system 1900 (e.g., using any of a variety of generally available compilers, installation programs, compression/decompression utilities, etc.), may take the form of executable code.

In some embodiments, memory 1920 may store a plurality of application modules 1922 through 1924, which may include any number of applications. Examples of applications may include gaming applications, conferencing applications, video playback applications, or other suitable applications. The applications may include a depth sensing function or eye tracking function. Application modules 1922-1924 may include particular instructions to be executed by processor(s) 1910. In some embodiments, certain applications or parts of application modules 1922-1924 may be executable by other hardware modules 1980. In certain embodiments, memory 1920 may additionally include secure memory, which may include additional security controls to prevent copying or other unauthorized access to secure information.

In some embodiments, memory 1920 may include an operating system 1925 loaded therein. Operating system 1925 may be operable to initiate the execution of the instructions provided by application modules 1922-1924 and/or manage other hardware modules 1980 as well as interfaces with a wireless communication subsystem 1930 which may include one or more wireless transceivers. Operating system 1925 may be adapted to perform other operations across the components of electronic system 1900 including threading, resource management, data storage control and other similar functionality.

Wireless communication subsystem 1930 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 1900 may include one or more antennas 1934 for wireless communication as part of wireless communication subsystem 1930 or as a separate component coupled to any portion of the system. Depending on desired functionality, wireless communication subsystem 1930 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 1930 may permit data to be exchanged with a network, other computer systems, and/or any other devices described herein. Wireless communication subsystem 1930 may include a means for transmitting or receiving data, such as identifiers of HMD devices, position data, a geographic map, a heat map, photos, or videos, using antenna(s) 1934 and wireless link(s) 1932. Wireless communication subsystem 1930, processor(s) 1910, and memory 1920 may together comprise at least a part of one or more of a means for performing some functions disclosed herein.

Embodiments of electronic system 1900 may also include one or more sensors 1990. Sensor(s) 1990 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 1990 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 1900 may include a display module 1960. Display module 1960 may be a near-eye display, and may graphically present information, such as images, videos, and various instructions, from electronic system 1900 to a user. Such information may be derived from one or more application modules 1922-1924, virtual reality engine 1926, one or more other hardware modules 1980, a combination thereof, or any other suitable means for resolving graphical content for the user (e.g., by operating system 1925). Display module 1960 may use LCD technology, LED technology (including, for example, OLED, ILED, μ-LED, AMOLED, TOLED, etc.), light emitting polymer display (LPD) technology, or some other display technology.

Electronic system 1900 may include a user input/output module 1970. User input/output module 1970 may allow a user to send action requests to electronic system 1900. An action request may be a request to perform a particular action. For example, an action request may be to start or end an application or to perform a particular action within the application. User input/output module 1970 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 1900. In some embodiments, user input/output module 1970 may provide haptic feedback to the user in accordance with instructions received from electronic system 1900. For example, the haptic feedback may be provided when an action request is received or has been performed.

Electronic system 1900 may include a camera 1950 that may be used to take photos or videos of a user, for example, for tracking the user's eye position. Camera 1950 may also be used to take photos or videos of the environment, for example, for VR, AR, or MR applications. Camera 1950 may include, for example, a complementary metal—oxide—semiconductor (CMOS) image sensor with a few millions or tens of millions of pixels. In some implementations, camera 1950 may include two or more cameras that may be used to capture 3-D images.

In some embodiments, electronic system 1900 may include a plurality of other hardware modules 1980. Each of other hardware modules 1980 may be a physical module within electronic system 1900. While each of other hardware modules 1980 may be permanently configured as a structure, some of other hardware modules 1980 may be temporarily configured to perform specific functions or temporarily activated. Examples of other hardware modules 1980 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 1980 may be implemented in software.

In some embodiments, memory 1920 of electronic system 1900 may also store a virtual reality engine 1926. Virtual reality engine 1926 may execute applications within electronic system 1900 and receive position information, acceleration information, velocity information, predicted future positions, or any combination thereof of the HMD device from the various sensors. In some embodiments, the information received by virtual reality engine 1926 may be used for producing a signal (e.g., display instructions) to display module 1960. For example, if the received information indicates that the user has looked to the left, virtual reality engine 1926 may generate content for the HMD device that mirrors the user's movement in a virtual environment. Additionally, virtual reality engine 1926 may perform an action within an application in response to an action request received from user input/output module 1970 and provide feedback to the user. The provided feedback may be visual, audible, or haptic feedback. In some implementations, processor(s) 1910 may include one or more GPUs that may execute virtual reality engine 1926.

In various implementations, the above-described hardware and modules may be implemented on a single device or on multiple devices that can communicate with one another using wired or wireless connections. For example, in some implementations, some components or modules, such as GPUs, virtual reality engine 1926, and applications (e.g., tracking application), may be implemented on a console separate from the head-mounted display device. In some implementations, one console may be connected to or support more than one HMD.

In alternative configurations, different and/or additional components may be included in electronic system 1900. Similarly, functionality of one or more of the components can be distributed among the components in a manner different from the manner described above. For example, in some embodiments, electronic system 1900 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code.

A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

From the foregoing, it will be seen that this invention is one well adapted to attain all the ends and objects set forth above, together with other advantages which are obvious and inherent to the system and method. It will be understood that certain features and subcombinations are of utility and may be employed without reference to other features and subcombinations. This is contemplated by and is within the scope of the claims.

The subject matter of the present invention is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A light source comprising:
a first semiconductor die that includes a light emitting device (LED) having a light emitting surface (LES) that emits light out of the LED with a first beam divergence; and
a second semiconductor die, bonded to the first semiconductor die, that includes a waveguide comprising:
a first waveguide surface that is configured to receive the light emitted by the LES of the LED with the first beam divergence;
a second waveguide surface; and
a waveguide body comprising a transparent crystalline material that transmits the light received by the first waveguide surface to the second waveguide surface, wherein the second waveguide surface and the waveguide body are configured such that the second waveguide surface emits the light, received by the first waveguide surface, out of the waveguide with a second beam divergence that is less than the first beam divergence.

2. The light source of claim 1, wherein the waveguide body has a tapered shape having a tapering angle associated with a growth process of the transparent crystalline material on a semiconductor substrate such that a first surface area of the first waveguide surface is less than a second surface area of the second waveguide surface.

3. The light source of claim 1, wherein the waveguide body has a mesa shape formed at least in part by removing a portion of the transparent crystalline material from the second semiconductor die via an etching process.

4. The light source of claim 1, wherein the waveguide further comprises:
a reflective layer that encapsulates a portion of the waveguide body and is configured to decrease a transmission loss associated with the waveguide body and decrease the beam divergence of the light received by the first waveguide surface.

5. The light source of claim 1, wherein the second semiconductor die further includes:
a first dielectric layer that encapsulates at least a portion of the waveguide body.

6. The light source of claim 5, wherein the first dielectric layer covers the first waveguide surface and the second semiconductor die further includes:
a second dielectric layer that covers the second waveguide surface; and
a layer of the transparent crystalline material is interposed between the first and second dielectric layers.

7. The light source of claim 1, wherein the second semiconductor die further includes:
a non-transparent baffle structure positioned around at least a portion of a perimeter of the second waveguide surface and extended beyond a plane of the second semiconductor die to define a columnar volume extending beyond the plane of the second semiconductor die, wherein the baffle structure is configured to confine a transmission, of the light emitted by the second waveguide surface and out of the second semiconductor die, within the columnar volume extending beyond the plane of the second semiconductor die.

8. The light source of claim 1, wherein the second waveguide surface has a curved shaped formed at least in part by removing a portion of the transparent crystalline material from the second semiconductor die via an etching process such that the second waveguide surface's curved shape is configured to decreases the beam divergence, of the light emitted by the second waveguide surface and out of the second semiconductor die.

9. The light source of claim 1, wherein a shape of the second waveguide surface is a planar shape and the second semiconductor die further includes:
a convex dielectric lens covering the second waveguide surface that receives the light emitted by the second waveguide surface with the second beam divergence, wherein the convex dielectric lens emits the light received by the convex lens with a third beam divergence that is less than the second beam divergence.

10. The light source of claim 1, further comprising:
a transparent glass substrate bonded to the second semiconductor die and covering the second waveguide surface, such that the second semiconductor die is interposed between the first semiconductor die and the glass substrate.

11. The light source of claim 1, wherein the transparent crystalline material is gallium nitride (GaN) grown on a semiconductor substrate.

12. The light source of claim 1, wherein:
the first semiconductor die includes an array of LEDs that includes the LED; and
the second semiconductor die includes an array of waveguides that includes the waveguide, wherein there is a one-to-one correspondence between each LED of the array of LEDs and each waveguide of the array of waveguides such that the LED uniquely corresponds to the waveguide.

13. The light source of claim 12, wherein the array of waveguides is formed on a continuous layer of the transparent crystalline material, a waveguide body of each waveguide of the array of waveguides protrudes from the continuous layer of the transparent crystalline material, a proximal surface of each waveguide of the array of waveguides includes a portion of the continuous layer of transparent crystalline material, and a distal surface of each waveguide of the array of waveguides is displaced from the continuous layer of the transparent crystalline material.

14. The light source of claim 12, wherein the array of waveguides is formed on a discontinuous layer of the transparent crystalline material that includes an array of separate dielectric layer portions formed via an etching process and there is a one-to-one correspondence between each dielectric layer portion of the array of separate dielectric layer portions and each waveguide of the array of waveguides.

15. The light source of claim 1, wherein the light source is included in a wearable device that generates at least one of a virtual reality environment or an augmented reality environment for a user wearing the wearable device.

16. The light source of claim 1, wherein an optical coupling efficiency between the LED and the waveguide is at least 0.70.

17. The light source of claim 1, wherein each spatial dimension of each imperfection in an optical surface finish of the waveguide is less than 5 nanometers (nm).

18. The light source of claim 1, wherein the LED is a micro light emitting diode and a spatial dimension of the LES of the LED is less than 10 micrometers.

19. A method of manufacturing a light source the method comprising. fabricating a first semiconductor die that includes a light emitting device (LED) having a light emitting surface (LES) that emits light out of the LED with a first beam divergence;
fabricating a second semiconductor die that includes a waveguide having a first wave guide surface, a second waveguide surface, and a waveguide body comprising a transparent crystalline material; and
bonding the second semiconductor die to the first semiconductor die such the first waveguide surface is configured to receive the light emitted by the LES of the LED with the first beam divergence, wherein the waveguide body is configured to transmit the light received by the first waveguide surface to the second waveguide surface, and the second waveguide surface is configured to emit the light, received by the first waveguide surface, out of the waveguide with a second beam divergence that is less than the first beam divergence.

20. A device comprising:
a first semiconductor die that includes a light emitting device (LED) having a light emitting surface (LES) that emits light out of the LED with a first beam divergence; and
a second semiconductor die, bonded to the first semiconductor die, that includes a waveguide comprising:
a first waveguide surface that is configured to receive the light emitted by the LES of the LED with the first beam divergence;
a second waveguide surface; and
a waveguide body comprising a transparent crystalline material that transmits the light received by the first waveguide surface to the second waveguide surface, wherein the second waveguide surface and the waveguide body are configured such that the second waveguide surface emits the light, received by the first waveguide surface, out of the waveguide with a second beam divergence that is less than the first beam divergence
